(19) United States
(12) Patent Application Publication
(10) Pub. No.: US 2024/0206191 A1
(43) Pub. Date: Jun. 20, 2024

(54) FERROELECTRIC MEMORY DEVICE AND METHOD FOR FORMING THE SAME

(71) Applicant: Wuxi Smart Memories Technologies Co., Ltd., Wuxi (CN)

(72) Inventors: Meilan Guo, Wuxi (CN); Yushi Hu, Wuxi (CN); Zhenyu Lu, Wuxi (CN); Jianhua Sun, Wuxi (CN)

(73) Assignee: Wuxi Smart Memories Technologies Co., Ltd., Wuxi (CN)

(21) Appl. No.: 18/595,939

(22) Filed: Mar. 5, 2024

Related U.S. Application Data
(63) Continuation of application No. PCT/CN2021/117067, filed on Sep. 8, 2021.

(51) Int. Cl. H10B 53/30; H10B 53/40

(52) U.S. Cl. CPC H10B 53/30; H10B 53/40

(57) ABSTRACT

A memory device includes a plurality of memory cells and a periphery circuit. Each memory cell includes at least one first transistor, at least one first interconnection layer formed over the first transistor and in electrical contact with the at least one transistor, and at least one capacitor electrically coupled to the at least one first transistor through the at least one first interconnection layer. A routing structure disposed over the plurality of memory cells and the periphery circuit to electrically connect the plurality of memory cells and the periphery circuit. A second interconnection layer is disposed over the routing structure. The at least one capacitor is disposed between the routing structure and a topmost conductive layer of the at least one first interconnection layer. The second interconnection layer includes no more than one conductive layer.

### CROSS-REFERENCE TO RELATED APPLICATIONS

This application is a continuation of International Application No. PCT/CN2021/117067, filed on Sep. 8, 2021, which is incorporated herein by reference in its entirety.

### BACKGROUND

Embodiments of the present disclosure relate to memory devices and fabrication methods thereof, and specifically relate to ferroelectric memory devices and fabrication methods thereof.

The demand for a non-volatile memory that has low operational voltage, low power consumption, and high-speed operation suitable for various electronic equipment, such as portable terminals and integrated circuit (IC) cards, has increased. Ferroelectric memory, such as ferroelectric RAM (FeRAM or FRAM), uses a ferroelectric material layer to achieve non-volatility. A ferroelectric material has a nonlinear relationship between the applied electric field and the apparent stored charge and thus, can switch polarity in an electric field. Ferroelectric memory's advantages include low power consumption, fast write performance, and great maximum read/write endurance.

### SUMMARY

Embodiments of ferroelectric memory devices and fabrication methods thereof are disclosed herein.

In one aspect, a memory device is disclosed. The memory device includes a plurality of memory cells, a periphery circuit, and a routing structure. Each memory cell includes at least one first transistor, at least one first interconnection layer formed over the at least one first transistor and in electrical contact with the at least one first transistor, and at least one capacitor electrically coupled to the at least one first transistor through the at least one first interconnection layer. The capacitor includes a first electrode, a second electrode surrounding at least a first portion of the first electrode, the second electrode electrically contacting the at least one first interconnection layer, and a ferroelectric layer disposed between the first electrode and the second electrode. The periphery circuit is configured to control operations of the plurality of memory cells. The routing structure is disposed over the plurality of memory cells and the periphery circuit to electrically connect the plurality of memory cells and the periphery circuit. A second interconnection layer is disposed over the routing structure. The at least one capacitor is disposed between the routing structure and a topmost conductive layer of the at least one first interconnection layer. The second interconnection layer includes no more than one conductive layer.

In some embodiments, the routing structure includes a first routing layer in direct contact with the first electrode. In some embodiments, the routing structure includes a first routing layer in contact with the first electrode through a first via structure. In some embodiments, the ferroelectric layer includes HfOx, ZrOx, or a combination of HfOx and ZrOx.

In some embodiments, the periphery circuit further includes at least one second transistor, and a plurality of third interconnection layers electrically coupled to the at least one second transistor. The plurality of third interconnection layers are in contact with the routing structure through at least one second via structure.

In some embodiments, the routing structure further includes a second routing layer coplanar to the first routing layer in contact with the plurality of second interconnection layers through the at least one second via structure.

In another aspect, a memory device is disclosed. The memory device includes a plurality of memory cells and a periphery circuit. Each memory cell includes at least one first transistor, at least one first interconnection layer formed over the at least one first transistor and in electrical contact with the at least one first transistor, a first conductive layer formed over the at least one first interconnection layer, the first conductive layer electrically coupled to the at least one first transistor through the at least one first interconnection layer, and at least one capacitor formed on the first conductive layer. The capacitor includes a first electrode, a second electrode surrounding at least a first portion of the first electrode, the second electrode electrically contacting the first conductive layer, and a ferroelectric layer disposed between the first electrode and the second electrode. The periphery circuit is configured to control operations of the plurality of memory cells. The first electrode of the plurality of memory cells functions as a routing structure between the plurality of memory cells.

In some embodiments, the memory device further includes a barrier layer disposed between the first conductive layer and the second electrode. In some embodiments, the barrier layer includes tantalum or tantalum nitride.

In some embodiments, a width of the barrier layer is equal to or larger than a width of the second electrode. In some embodiments, the first electrode of one memory cell is in electric contact with the first electrode of another memory cell.

In some embodiments, the periphery circuit further includes at least one second transistor, and a plurality of second interconnection layers electrically coupled to the at least one second transistor. The plurality of second interconnection layers are in contact with the routing structure through at least one via structure.

In some embodiments, a first height of the at least one capacitor is equal to or less than a second height of the at least one via structure.

In still another aspect, a method for forming a ferroelectric memory cell is disclosed. A semiconductor structure is formed over a substrate, and the semiconductor structure includes a cell region and a periphery region. A first interconnection structure is formed over the cell region of the semiconductor structure, and a second interconnection structure is formed over the periphery region of the semiconductor structure. A dielectric layer is formed over the first interconnection structure and the second interconnection structure. A capacitor is formed in the dielectric layer above the first interconnection structure, and a via structure is formed in the dielectric layer above the second interconnection structure. A routing structure is formed over the capacitor and the via structure.

In some embodiments, a first opening is formed in the dielectric layer above the first interconnection structure. The capacitor is formed in the first opening. The ferroelectric memory includes a first electrode, a second electrode surrounding at least a first portion of the first electrode, and a ferroelectric layer disposed between the first electrode and the second electrode. A second opening is formed in the dielectric layer above the second interconnection structure. The via structure is formed in the second opening.

In some embodiments, a linear layer is formed over the capacitor and the via structure. In some embodiments, a first routing layer is formed in contact with the via structure, and a portion of the first electrode is utilized as a second routing layer. In some embodiments, a first routing layer is formed in contact with the via structure, and a second routing layer is formed in direct contact with the first electrode.

In some embodiments, a barrier layer is formed between the first interconnection structure and the capacitor. In some embodiments, the barrier layer includes tantalum or tantalum nitride.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIG. 1 illustrates a cross-section of an exemplary ferroelectric memory device, according to some aspects of the present disclosure.

FIG. 2 illustrates a cross-section of another exemplary ferroelectric memory device, according to some aspects of the present disclosure.

FIG. 3 illustrates a cross-section of a further exemplary ferroelectric memory device, according to some aspects of the present disclosure.

FIGS. 4-10 illustrate cross-sections of an exemplary ferroelectric memory device at different stages of a manufacturing process, according to some aspects of the present disclosure.

FIG. 11 illustrates a cross-section of another exemplary ferroelectric memory device at different stages of a manufacturing process, according to some aspects of the present disclosure.

FIGS. 12-18 illustrate cross-sections of a further exemplary ferroelectric memory device at different stages of a manufacturing process, according to some aspects of the present disclosure.

FIG. 19 illustrates a cross-section of a further exemplary ferroelectric memory device at different stages of a manufacturing process, according to some aspects of the present disclosure.

FIG. 20 illustrates a cross-section of a further exemplary ferroelectric memory device at different stages of a manufacturing process, according to some aspects of the present disclosure.

FIGS. 21-24 illustrate cross-sections of a further exemplary ferroelectric memory device at different stages of a manufacturing process, according to some aspects of the present disclosure.

FIG. 25 illustrates a cross-section of a further exemplary ferroelectric memory device at different stages of a manufacturing process, according to some aspects of the present disclosure.

FIG. 26 illustrates a cross-section of a further exemplary ferroelectric memory device at different stages of a manufacturing process, according to some aspects of the present disclosure.

FIG. 27 illustrates a cross-section of a further exemplary ferroelectric memory device at different stages of a manufacturing process, according to some aspects of the present disclosure.

FIGS. 28-32 illustrate cross-sections of a further exemplary ferroelectric memory device at different stages of a manufacturing process, according to some aspects of the present disclosure.

FIGS. 33-37 illustrate cross-sections of a further exemplary ferroelectric memory device at different stages of a manufacturing process, according to some aspects of the present disclosure.

FIG. 38 illustrates a flowchart of an exemplary method for forming a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, a “side surface” can generally refer to a surface on the exterior of an object. For example, depending on the embodiment, a side surface can be a sidewall along a horizontal direction (e.g., the x-direction) or a top/bottom surface along a vertical direction (e.g., the z-direction). As used herein, a recess refers to an open space between two boundaries. For example, depending on the embodiment, a recess can be located between two surfaces that are not coplanar with each other, e.g., having a staggered configuration.

A memory cell array of the ferroelectric memory device may include a number of bit lines and a number of word lines extending to cross with each other, and a number of memory cells may be arranged in a matrix at positions corresponding to the respective crossings of the lines. Each memory cell may include at least one memory cell transistor, in which the gate electrode of the memory cell transistor may receive a signal from the word line, and at least one ferroelectric capacitor interposed between the source region of the memory cell transistor and a cell plate line. The ferroelectric capacitor has a residual polarization characteristic to generate positive or negative residual polarizations depending on the high/low relationship between the voltage applied to the ferroelectric capacitor from the bit line via the memory cell transistor and the voltage applied to the ferroelectric capacitor from the cell plate line. Hence, one limitation of the ferroelectric memory device fabrication is the capacitance of the ferroelectric capacitor. Various embodiments in accordance with the present disclosure provide ferroelectric memory devices and fabrication methods thereof that can increase the capacitance of the ferroelectric capacitor.

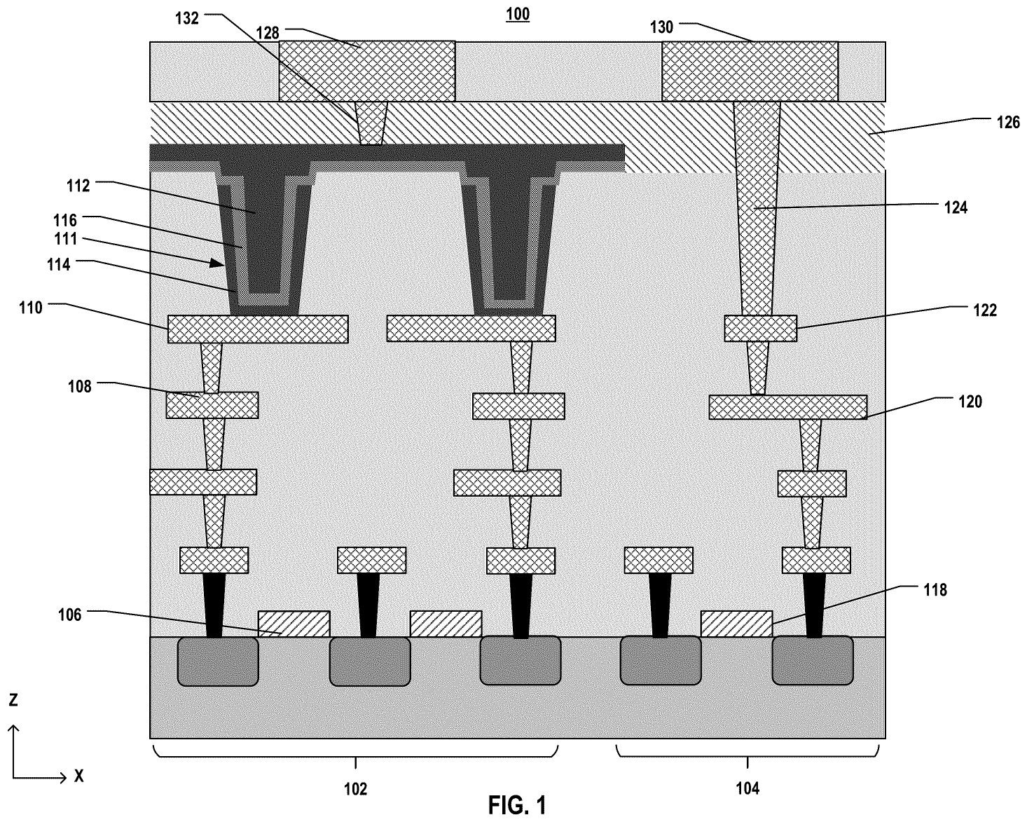

FIG. 1 illustrates a cross-section of an exemplary ferroelectric memory device 100, according to some aspects of the present disclosure. Ferroelectric memory device 100 includes at least one memory cell 102 and at least one periphery circuit 104.

Memory cell 102 includes at least one transistor 106, and an interconnection structure 108 disposed on transistor 106. In some embodiments, interconnection structure 108 may include one or more than one interconnection layer, as shown in FIG. 1. In some embodiments, interconnection structure 108 may electrically connect one of the terminals of transistor 106. In some embodiments, interconnection structure 108 may electrically connect the source/drain terminal of transistor 106.

A conductive plate 110 is formed over interconnection structure 108. In some embodiments, conductive plate 110 may be the cell landing island of ferroelectric memory device 100. At least one capacitor 111 is formed on conductive plate 110. Ferroelectric memory device 100 may include a plurality of memory cell 102, and each memory cell 102 may be the storage element of ferroelectric memory device 100, and may include various designs and configurations. FIG. 1 shows a “2T-2C” ferroelectric memory cell structure that includes two transistors and two capacitors. However, the amount of the transistors and/or the capacitors in ferroelectric memory device 100 is not limited hereto, and other suitable designs of ferroelectric memory cell structures, e.g., 1T-1C or nT-nC ferroelectric memory cell, are in the scope of the present disclosure.

Capacitor 111 is electrically coupled to transistor 106 through interconnection structure 108 and conductive plate 110. Capacitor 111 includes an electrode 112, and an electrode 114 surrounding at least a portion of electrode 112. In some embodiments, electrode 114 electrically contacts conductive plate 110. In some embodiments, electrode 114 directly contacts conductive plate 110. A ferroelectric layer 116 is disposed between electrode 112 and electrode 114.

Ferroelectric layer 116 may include oxygen and one or more ferroelectric metals. The ferroelectric metals may include, but not limited to, zirconium (Zr), hafnium (Hf), titanium (Ti), aluminum (Al), or other suitable materials. In some embodiments, ferroelectric layer 116 may include oxygen and two or more ferroelectric metals. In some embodiments, ferroelectric layer 116 may include oxygen and a non-metal material such as silicon (Si). Optionally, ferroelectric layer 116 may also include a plurality of dopants formed as a part of the crystal structures. In some embodiments, the dopants compensate for the defects formed during the crystallization of the ferroelectric oxide material to improve the film quality of ferroelectric layer 116. In some embodiments, the dopants are different from the ferroelectric metals in the ferroelectric oxide material and include one or more dopants from one or more of Hf, Zr, Ti, Al, Si, hydrogen (H), oxygen (O), vanadium (V), niobium (Nb), tantalum (Ta), yttrium (Y), and/or lanthanum (La). In some embodiments, ferroelectric layer 116 may include HfOx, ZrOx, or a combination of HfOx and ZrOx.

Periphery circuit 104 is configured to control operations of memory cell 102. Periphery circuit 104 may include at least one transistor 118, and an interconnection structure 120 electrically coupled to transistor 118. In some embodiments, the periphery circuit 104 comprises a plate line driver. In some embodiments, interconnection structure 120 may include one or more than one interconnection layers, as shown in FIG. 1. In some embodiments, interconnection structure 120 may electrically connect one of the terminals of transistor 118. In some embodiments, interconnection structure 120 may electrically connect the source/drain terminal of transistor 118.

A conductive plate 122 is formed over interconnection structure 120. In some embodiments, conductive plate 122 may be a metal layer of periphery circuit 104. A via structure 124 is formed on conductive plate 122. As shown in FIG. 1, in some embodiments, the height of capacitor 111 is less than the height of via structure 124. In some embodiments, the height of capacitor 111 is less than the height of a stack of via structure 124 and conductive plate 122.

A dielectric layer 126 may be formed over memory cell 102 and periphery circuit 104, and a routing structure may be formed in or over dielectric layer 126. The routing structure includes a routing layer 128 and a routing layer 130. Routing layer 128 is electrically connected to electrode 112 through a via structure 132, and routing layer 130 is electrically connected to via structure 124. In some embodiments, an interconnection structure may be further formed over the routing structure, wherein the interconnection layer comprises no more than one conductive layer. In some embodiments, there is no interconnection structure over the routing structure and no conductive layer is formed over the routing structure. The description of “formed over” here means formed in the space directly above the memory cell area. In other words, there is no more than one conductive layer directly above and overlaps the memory cell area. The memory cell should be a functional cell, not the dummy cells. In this case, even the pad layer should not be directly above the memory cell area.

In some embodiments, the routing structure may include no more than one conductive layer. In some embodiments, the routing structure may include no more than one conductive layer and one via structure. In some embodiments, the interconnection structure over the routing structure may include no more than one conductive layer. In some embodiments, the interconnection structure over the routing structure may include no more than one conductive layer and no more than one via structure. The description of “one conductive layer” here means one conductive layer formed in the same manufacturing process and may have the same material. For example, routing layer 128 and routing layer 130 may be formed in the same manufacturing process and include the same material, and routing layer 128 and routing layer 130 are defined as “one conductive layer” in the present disclosure.

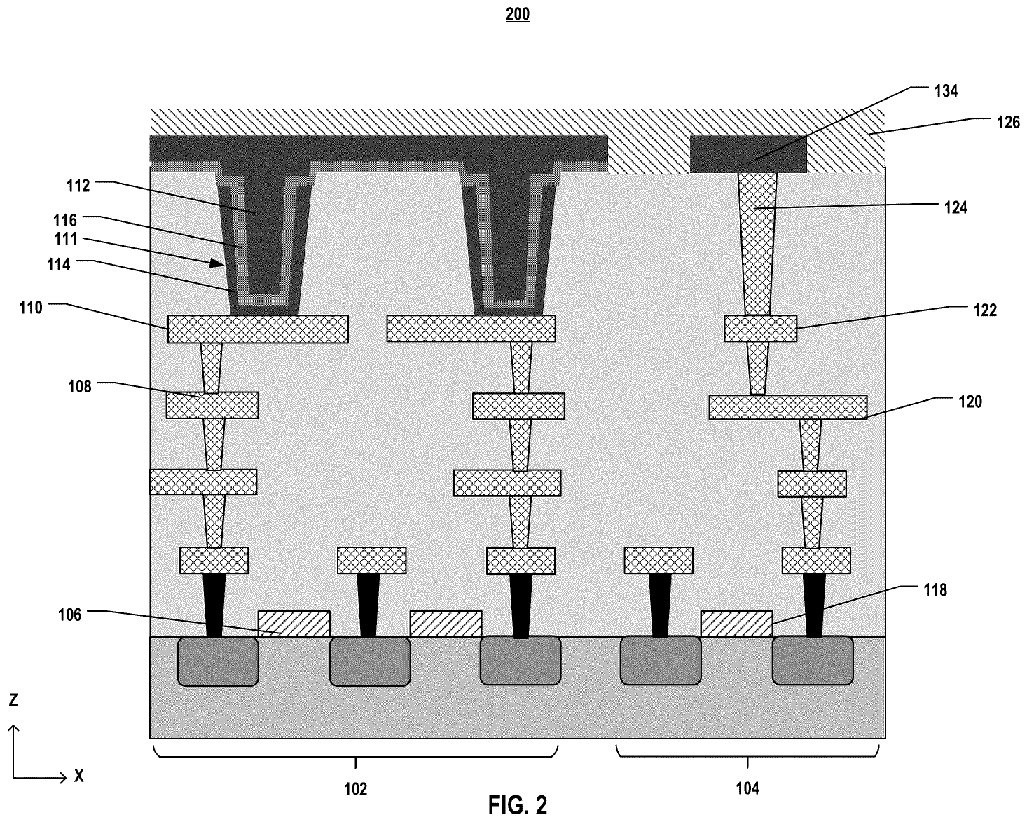

FIG. 2 illustrates a cross-section of another exemplary ferroelectric memory device 200, according to some aspects of the present disclosure. Ferroelectric memory device 200 is similar to ferroelectric memory device 100, but electrode 112 may be applied as the routing structure in ferroelectric memory device 200.

As shown in FIG. 2, dielectric layer 126 may be formed over electrode 112, and a portion of the routing structure is formed by electrode 112. A routing layer 134 may be formed on via structure 124. In some embodiments, routing layer 134 and electrode 112 may include the same material. In some embodiments, routing layer 134 and electrode 112 may include different materials. In some embodiments, the height of capacitor 111 is less than the height of via structure 124. In some embodiments, the height of capacitor 111 is less than the height of a stack of via structure 124 and routing layer 134.

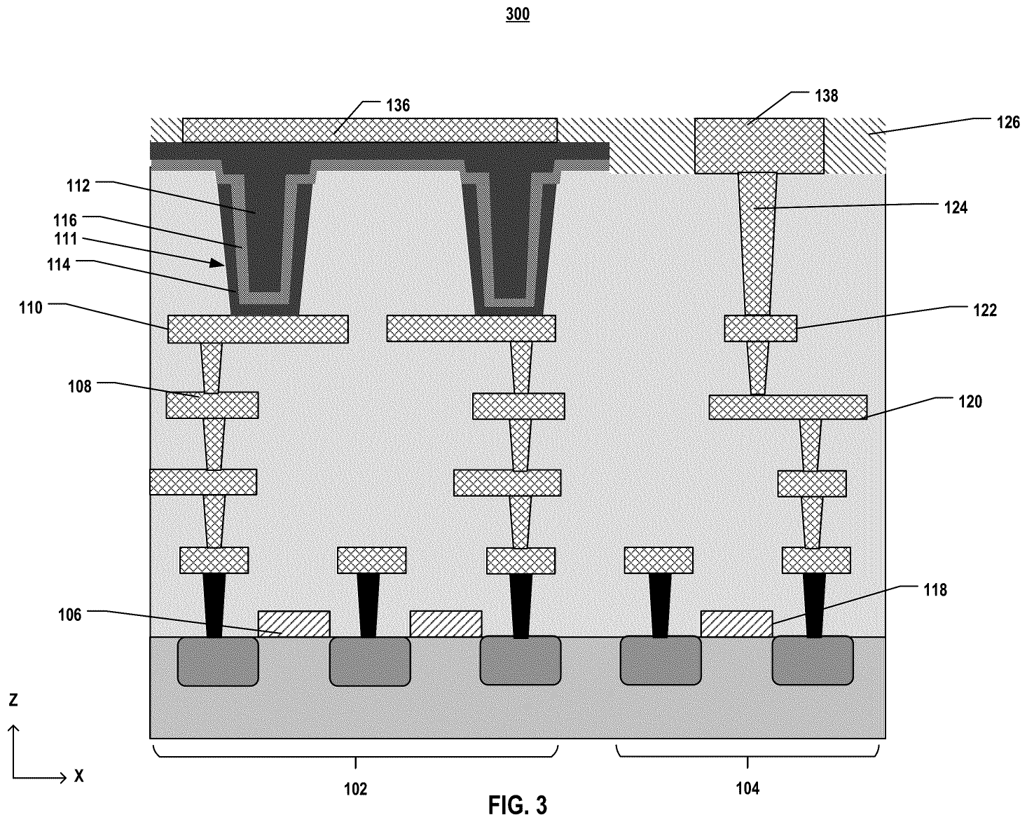

FIG. 3 illustrates a cross-section of a further exemplary ferroelectric memory device 300, according to some aspects of the present disclosure. Ferroelectric memory device 300 is similar to ferroelectric memory device 100, but a routing layer 136 is formed over electrode 112 in direct contact with electrode 112.

As shown in FIG. 3, dielectric layer 126 may be formed over electrode 112 and via structure 124, and routing layer 136 is formed in dielectric layer 126 and over electrode 112 in direct contact with electrode 112. A routing layer 138 is formed in dielectric layer 126 and in direct contact with via structure 124. In some embodiments, the height of capacitor 111 is less than the height of via structure 124. In some embodiments, the height of capacitor 111 is less than the height of a stack of via structure 124 and routing layer 138.

In some embodiments, as shown in FIG. 1, the routing structure comprises a metal layer and a via. The electrode 112 of capacitor 111 is connected with the metal layer 128 through a via 132. The metal layer 128 and metal layer 130 are in contact. The routing structure, consequently, electrically connects the capacitor with the periphery circuit 104. In some embodiments, as shown in FIG. 2, the routing structure comprises a portion of the electrode 112 and routing layer 134 without additional vias or metal layers. In some embodiments, the routing layer 134 and the electrode 112 are in contact and are formed in the same process. The routing layer 134 and the electrode 112 electrically connect the capacitor 111 with the periphery circuit 104. In some embodiments, as shown in FIG. 3, the routing structure comprises a metal layer without vias. The metal layer 136 is in contact with the electrode 112 without vias, thus saving a mask layer. The metal layer 136 and metal layer 138 are in contact and are formed in the same process. In some embodiments, metal layer 138 and metal layer 136 have different thicknesses due to the presence of the capacitor 111 under metal layer 136. The routing structure comprises a metal layer with no via. In these embodiments, the routing structure above the memory cell 102 comprises no more than one metal layer. Accordingly, as shown in FIGS. 1-3, via structure 124 and routing layer 130, 134, or 138 are designed as the topmost metal structure of periphery circuit 104. The routing above the capacitor in the periphery circuit area comprises also no more than one metal layer.

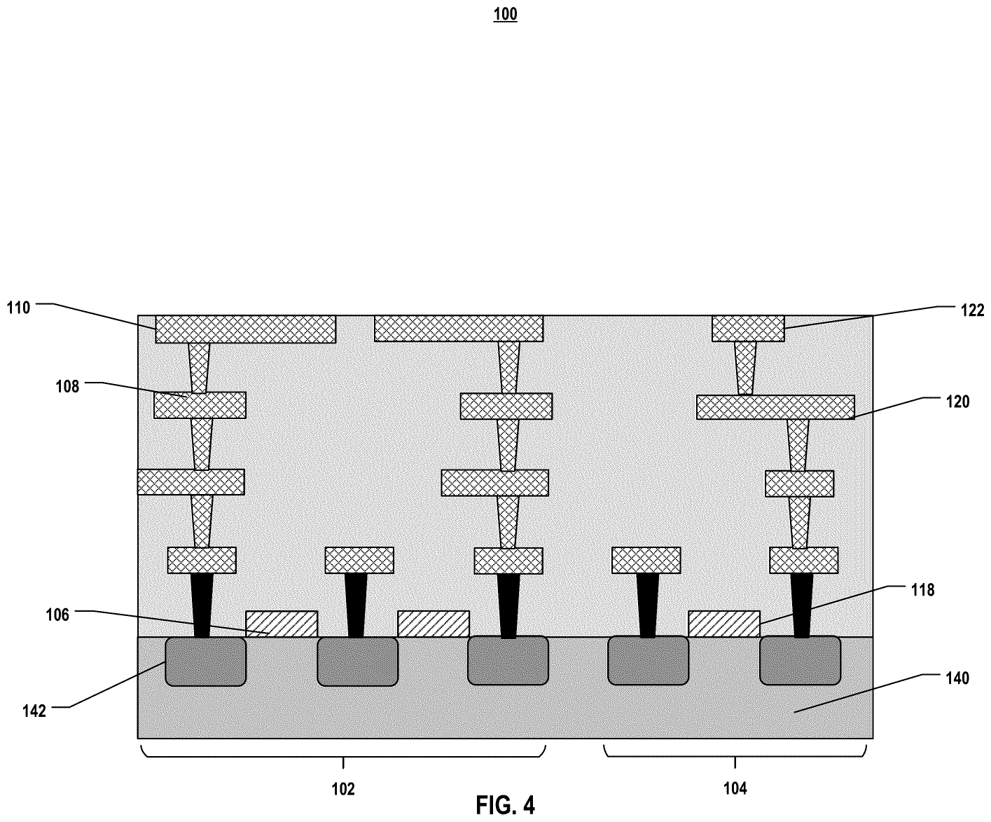

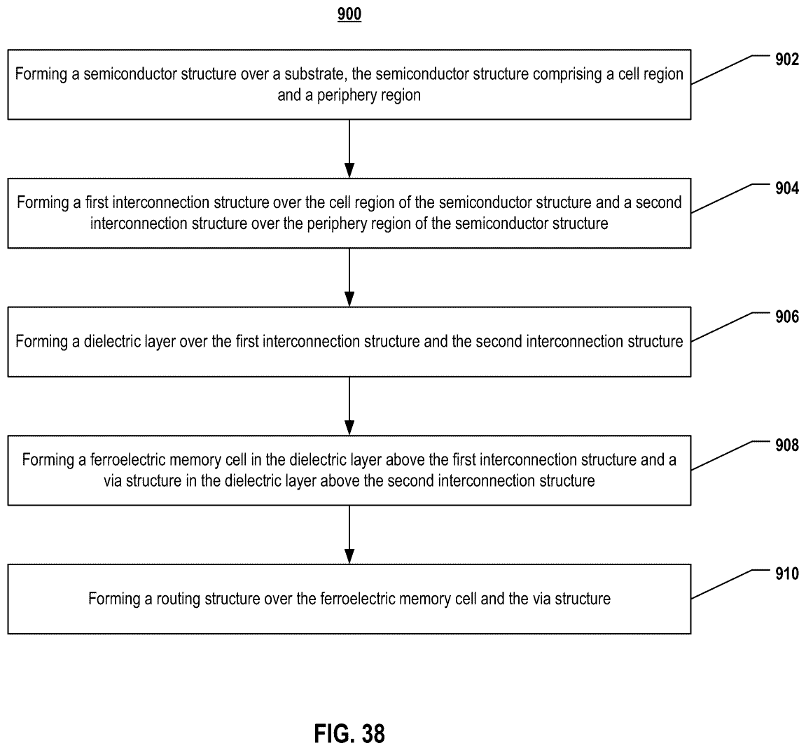

In some embodiments, conductive plate 110 and conductive plate 122 are formed in the same process. In some embodiments, conductive plate 110 and conductive plate 122 may include the same material. Hence, capacitor 111 may be disposed between the area corresponding to the topmost metal layer and the penultimate metal layer of periphery circuit 104. Typically, the space between the topmost metal layer and the penultimate metal layer of periphery circuit 104 has the largest thickness of the metal structure of periphery circuit 104. When forming capacitor 111 in this area, capacitor 111 may have a larger cell area and enough charge for memory sensing. Capacitor 111 is therefore, may be disposed in the area corresponding to one single metal structure layer, e.g., the stack of via structure 124 and routing layer 130, 134, or 138, instead of occupying multiple layers of metal structures. By using this structure, the manufacturing process may be simplified and the reliability of the memory cells may also be improved. FIGS. 4-10 illustrate cross-sections of ferroelectric memory device 100 at different stages of a manufacturing process, according to some aspects of the present disclosure. FIG. 38 illustrates a flowchart of an exemplary method 900 for forming a memory device, according to some aspects of the present disclosure. For the purpose of better explaining the present disclosure, the cross-sections of ferroelectric memory device 100 in FIGS. 4-10 and the flowchart of method 900 in FIG. 38 will be described together. It is understood that the operations shown in method 900 are not exhaustive and that other operations can be performed as well before, after, or between any of the illustrated operations. Further, some of the operations may be performed simultaneously, or in a different order than shown in FIGS. 4-10 and FIG. 38.

As shown in FIG. 4 and operation 902 in FIG. 38, a semiconductor structure is formed over a substrate 140. The semiconductor structure includes memory cell 102 (the cell region) and periphery circuit 104 (the periphery region). Substrate 140 may include silicon (e.g., single crystalline silicon), silicon germanium (SiGe), gallium arsenide (GaAs), germanium (Ge), silicon on insulator (SOI), or other suitable materials. The semiconductor structure may include transistors 106 and 118, as shown in FIG. 4. Each of transistors 106 and 118 may include a gate stack having a gate dielectric and a gate conductor formed on substrate 140, and source/drain regions 142 are formed in substrate 140. Source/drain regions 142 may be doped portions in the substrate with n-type or p-type dopants at a desired doping level. The gate dielectric may include dielectric materials, such as silicon oxide (SiOₓ), silicon nitride (SiNₓ) or high-k dielectric materials including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. The gate conductor may include conductive materials including, but not limited to, tungsten (W), cobalt (Co), copper (Cu), Al, polysilicon, silicide, or any combination thereof. The gate conductor may function as the word line of ferroelectric memory device 100.

As shown in FIG. 4 and operation 904 in FIG. 38, interconnection structure 108 is formed over the cell region of the semiconductor structure, and interconnection structure 120 is formed over the periphery region of the semiconductor structure. Conductive plate 110 is formed on interconnection structure 108, and conductive plate 122 is formed on interconnection structure 120. Interconnection structure 108 and a conductive plate 110 may be in contact with one of the source/drain regions and electrically coupled to an electrode of a capacitor formed in subsequent operations. In some embodiments, interconnection structure 108, and conductive plate 110 may include Cu, titanium nitride (TiN) or W.

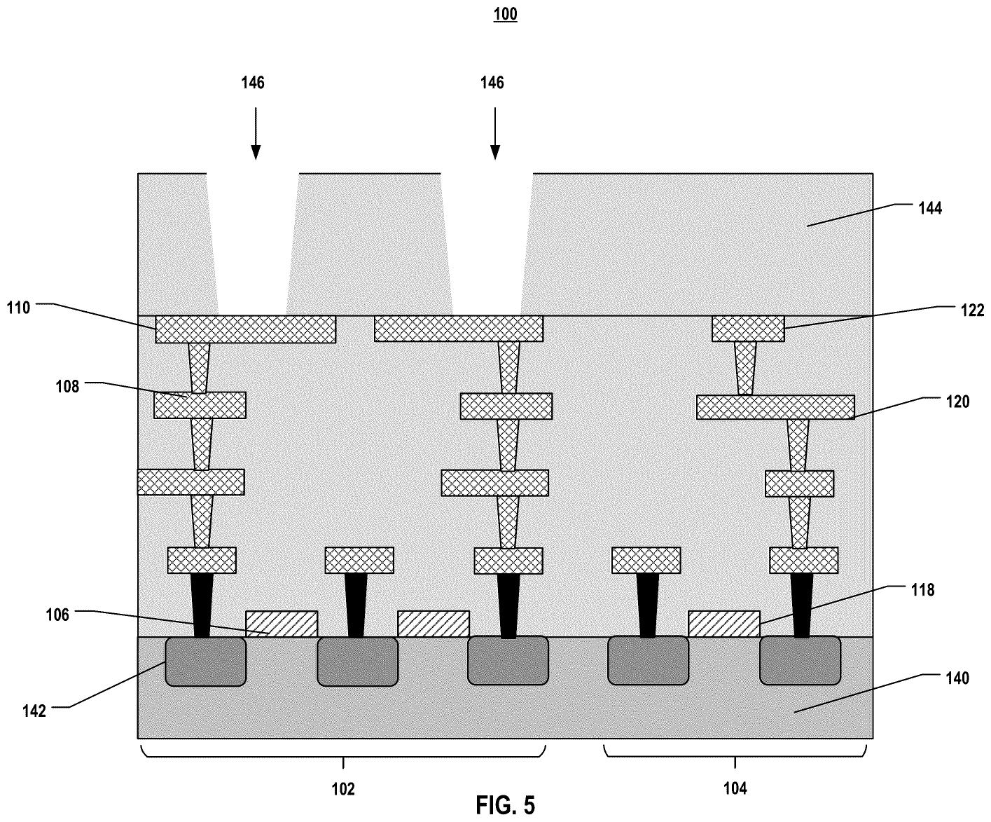

As shown in FIG. 5 and operation 906 in FIG. 38, a dielectric layer 144 is formed over interconnection structure 108 and interconnection structure 120. In some embodiments, dielectric layer 144 may include an interlayered dielectric (ILD) layer, such as SiOₓ or SiNₓ. Then, as shown in operation 908 in FIG. 38, capacitor 111 is formed in dielectric layer 144 above interconnection structure 108, and via structure 124 is formed in dielectric layer 144 above interconnection structure 120. In some embodiments, capacitor 111 is formed in dielectric layer 144 before the formation of via structure 124. In some embodiments, via structure 124 is formed in dielectric layer 144 before the formation of capacitor 111. In some embodiments, capacitor 111 and via structure 124 are formed in dielectric layer 144 during the same manufacturing processes.

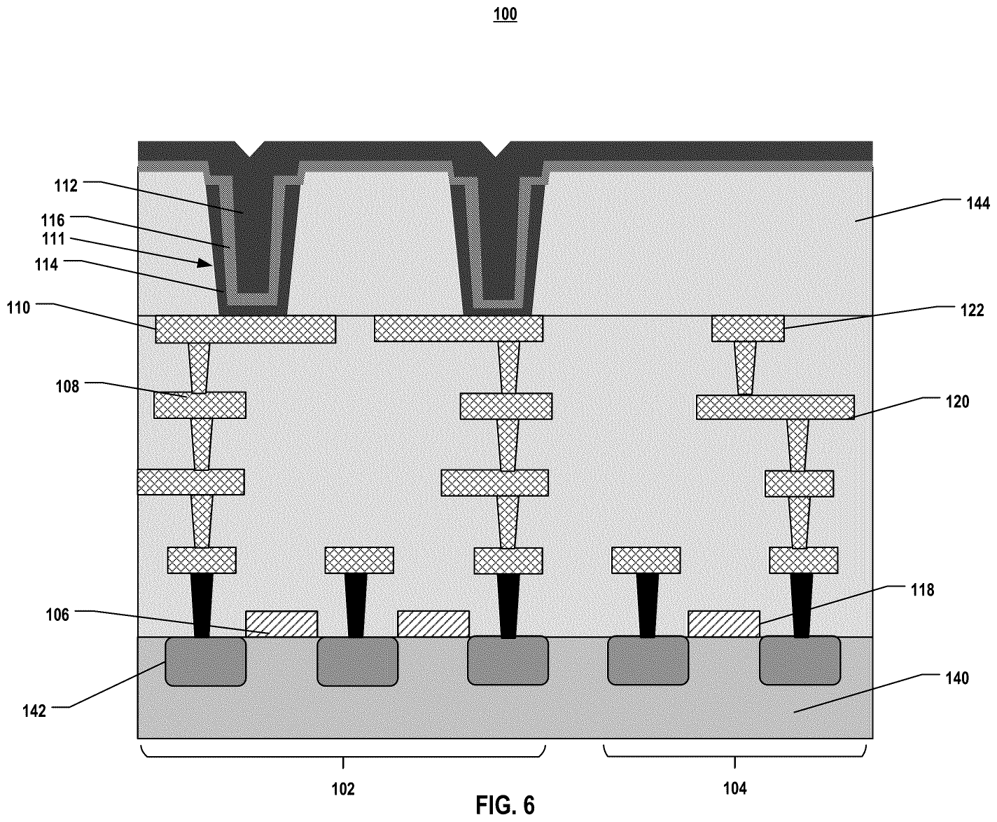

As shown in FIG. 5, openings 146 are formed in dielectric layer 144 to expose the top surface of conductive plates 110. Openings 146 may be formed by dry etch, wet etch, or other suitable processes. Then, as shown in FIG. 6, electrode 114, ferroelectric layer 116, and electrode 112 are sequentially and conformally formed in openings 146. Electrode 114 electrically contacts conductive plates 110. In some embodiments, electrode 114 and electrode 112 may include TiN, titanium silicon nitride (TiSiNₓ), titanium aluminum nitride (TiAlNₓ), titanium carbon nitride (TiCNₓ), tantalum nitride (TaNₓ), tantalum silicon nitride (TaSiNₓ), tantalum aluminum nitride (TaAlNₓ), tungsten nitride (WNₓ), tungsten silicide (WSiₓ), tungsten carbon nitride (WCNₓ), ruthenium (Ru), ruthenium oxide (RuOₓ), iridium (Ir), doped polysilicon, transparent conductive oxides (TCO), iridium oxide (IrOₓ), or other suitable materials. In some embodiments, electrode 114 and electrode 112 may include the same material(s). In some embodiments, electrode 114 and electrode 112 may include different materials.

In some embodiments, electrode 114 and electrode 112 may be formed by atomic layer deposition (ALD), physical vapor deposition (PVD), chemical vapor deposition (CVD), electrochemical deposition, pulsed laser deposition (PLD), or other suitable processes. In some embodiments, electrode 114 and electrode 112 may have a thickness between about 2 nm and about 50 nm. In some embodiments, electrode 114 and electrode 112 may have the same thickness. In some embodiments, electrode 114 and electrode 112 may have different thicknesses.

In some embodiments, ferroelectric layer 116 may include a ferroelectric oxide material. The ferroelectric oxide may be doped with a plurality of dopants, which can improve ferroelectric film crystallization. For example, the dopants may provide elasticity during the crystallization of the doped ferroelectric layer, reducing the number of defects formed in the ferroelectric film crystallization, and improving high-K ferroelectric phase formation. It is understood that in some embodiments, ferroelectric layer 116 may include a multi-layer structure.

In some embodiments, ferroelectric layer 116 may include a ferroelectric composite oxide. In some embodiments, ferroelectric layer 116 may include oxygen and one or more ferroelectric metals. The ferroelectric metals can include, but not limited to, zirconium (Zr), hafnium (Hf), titanium (Ti), aluminum (Al), or other suitable materials. In some embodiments, ferroelectric layer 116 may include oxygen and two or more ferroelectric metals. In some embodiments, ferroelectric layer 116 may include oxygen and a non-metal material such as silicon (Si).

Optionally, ferroelectric layer 116 may also include a plurality of dopants formed as a part of the crystal structures. In some embodiments, the dopants compensate for the defects formed during the crystallization of the ferroelectric oxide material to improve the film quality of ferroelectric layer 116. In some embodiments, the dopants are different from the ferroelectric metals in the ferroelectric oxide material and include one or more dopants from one or more of Hf, Zr, Ti, Al, Si, hydrogen (H), oxygen (O), vanadium (V), niobium (Nb), tantalum (Ta), yttrium (Y), and/or lanthanum (La). In some embodiments, ferroelectric layer 116 may include HfOx, ZrOx, or a combination of HfOx and ZrOx.

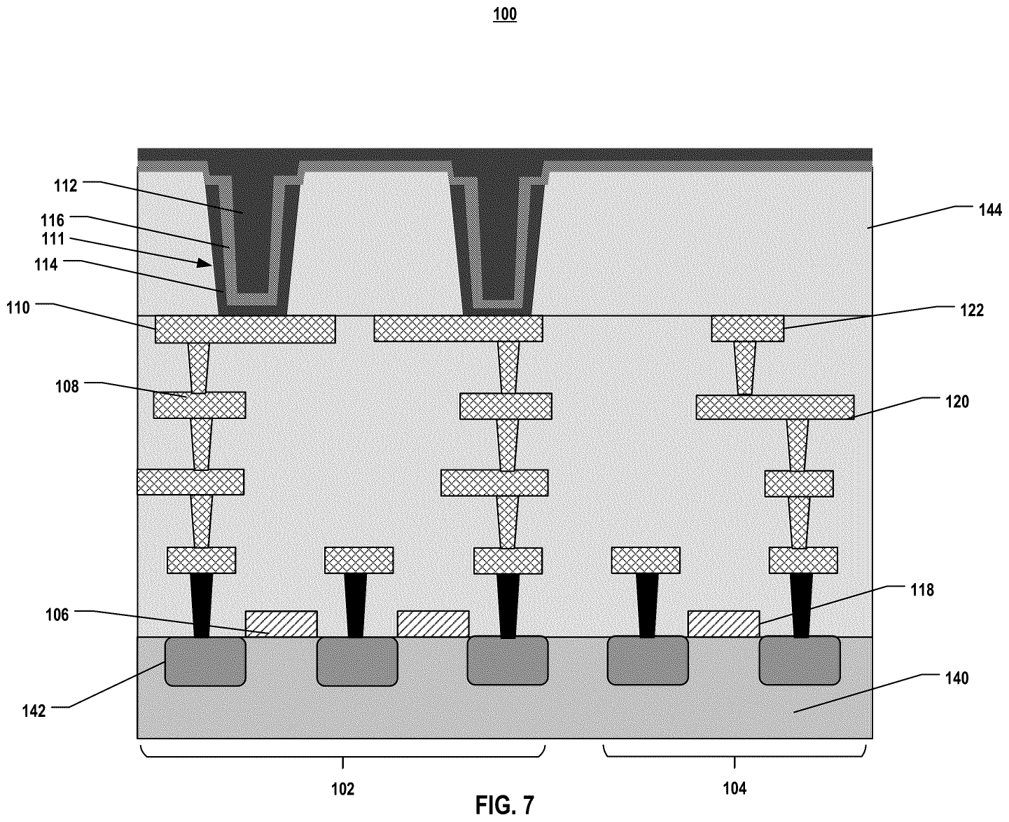

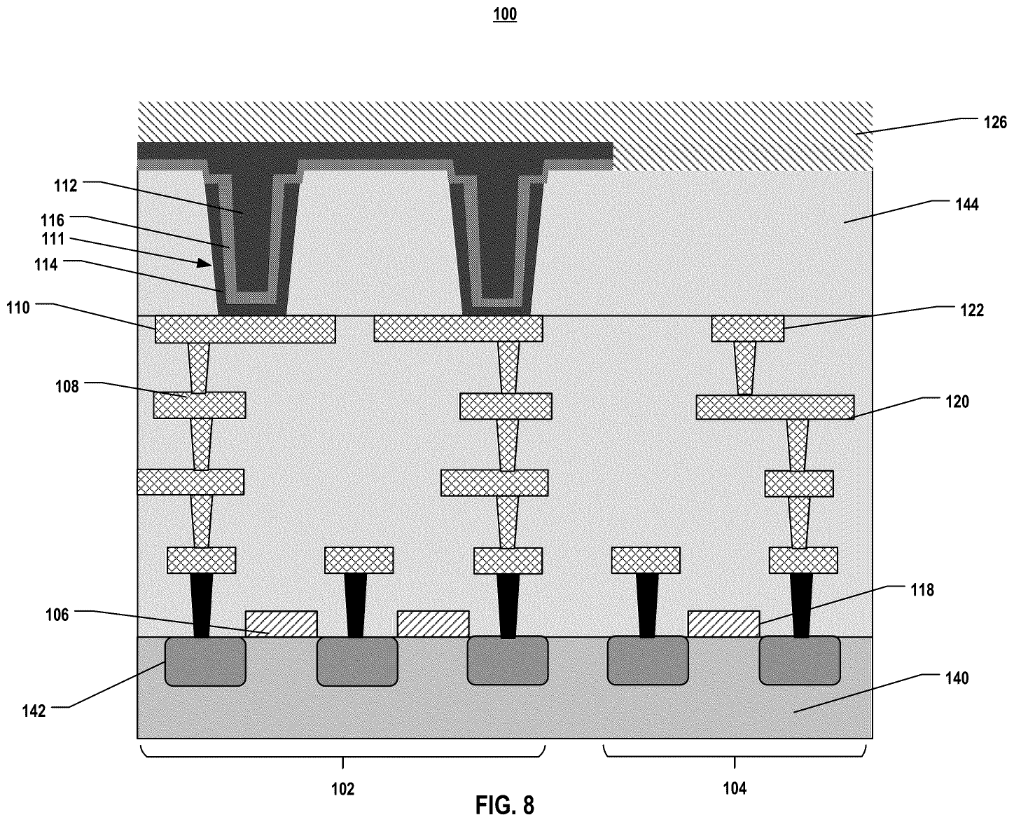

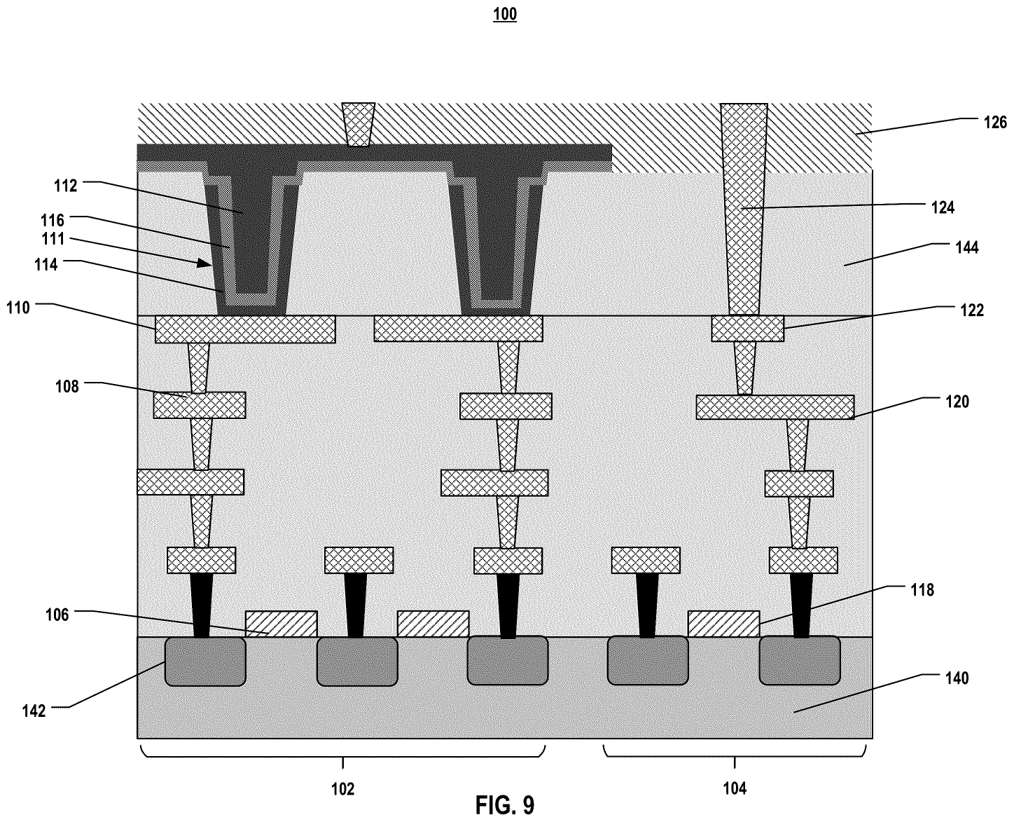

As shown in FIG. 7, a planarization operation may be performed to remove a portion of electrode 112. As shown in FIG. 8, portions of ferroelectric layer 116 and electrode 112 above periphery circuit 104 are removed, and a dielectric layer 126 is formed over electrode 112 and exposed dielectric layer 144. Then, as shown in FIG. 9, via structure 124 is formed in dielectric layer 144 and dielectric layer 126 in electric contact with conductive plate 122.

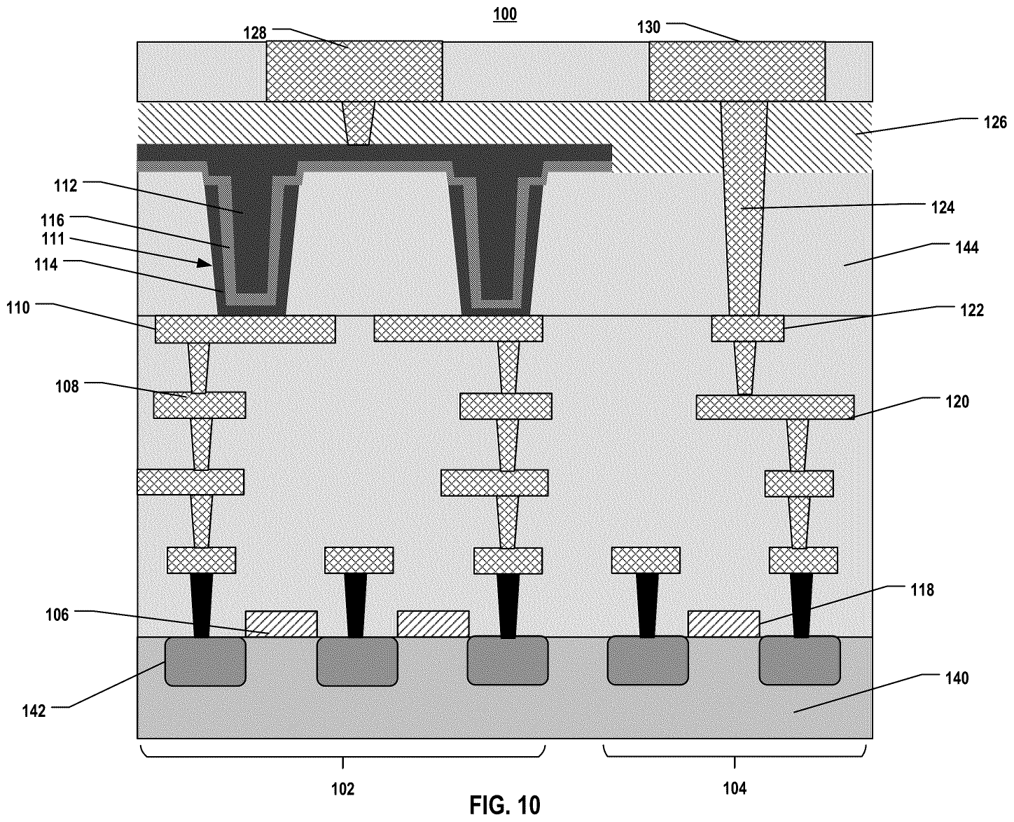

As shown in FIG. 10 and operation 910 in FIG. 38, routing layer 128 is formed over memory cell 102, and routing layer 130 is formed over periphery circuit 104. Via structure 124 and routing layer 130 are designed as a topmost metal structure of periphery circuit 104. In some embodiments, conductive plate 110 and conductive plate 122 are formed in the same process. In some embodiments, conductive plate 110 and conductive plate 122 may include the same material. Hence, capacitor 111 may be disposed between the area corresponding to the topmost metal layer and the penultimate metal layer of periphery circuit 104. Typically, the space between the topmost metal layer and the penultimate metal layer of periphery circuit 104 has a larger or largest thickness of the metal structure of periphery circuit 104. When forming capacitor 111 in this area, capacitor 111 may have a larger cell area and enough charge for memory sensing. Capacitor 111 is therefore, may be disposed in the area corresponding to one single metal structure, e.g., the stack of via structure 124 and routing layer 130, instead of occupying multiple layers of metal structures. By using this structure, the manufacturing process may be simplified, and the reliability of the memory cells may also be improved.

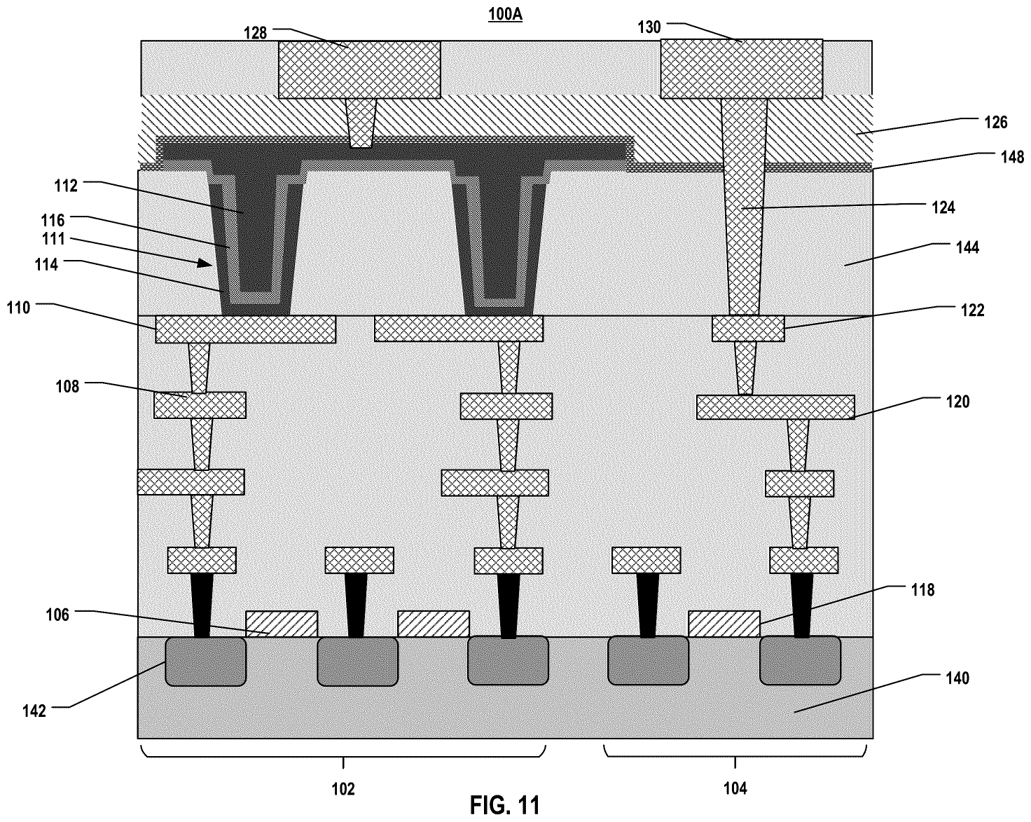

FIG. 11 illustrates a cross-section of another exemplary ferroelectric memory device 100A at different stages of a manufacturing process, according to some aspects of the present disclosure. The structure of ferroelectric memory device 100A is similar to the structure of ferroelectric memory device 100, and a protection layer 148 may be disposed over dielectric layer 144 and electrode 112. As shown in FIG. 11, before forming dielectric layer 126, protection layer 148 is deposited over dielectric layer 144 and electrode 112. In some embodiments, protection layer 148 may include AlOₓ. In some embodiments, protection layer 148 may include AlOₓ with SiN, SiON, or SiOC.

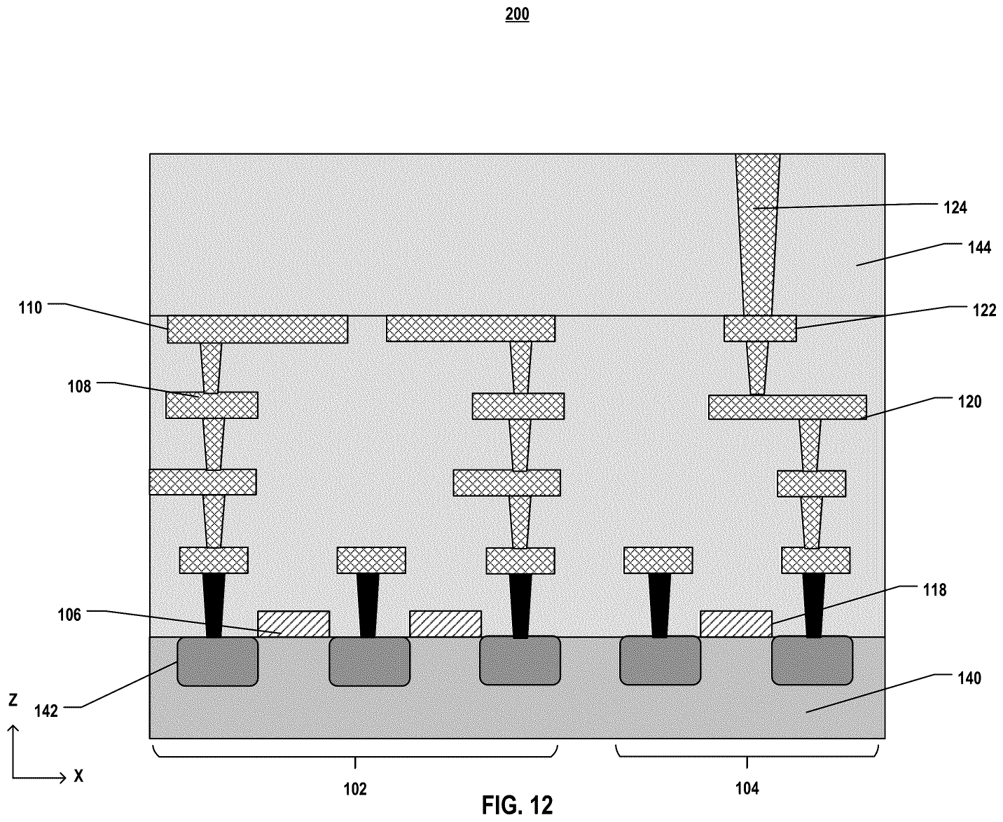

FIGS. 12-18 illustrate cross-sections of ferroelectric memory device 200 at different stages of a manufacturing process, according to some aspects of the present disclosure.

As shown in FIG. 12, the semiconductor structure is formed over substrate 140. The semiconductor structure includes memory cell 102 (the cell region) and periphery circuit 104 (the periphery region). The semiconductor structure may include transistors 106 and 118, and each of transistors 106 and 118 may include the gate structure and source/drain regions 142 formed in substrate 140. The gate structure may function as the word line of ferroelectric memory device 200. Interconnection structure 108 is formed over the cell region of the semiconductor structure, and interconnection structure 120 is formed over the periphery region of the semiconductor structure.

Conductive plate 110 is formed on interconnection structure 108, and conductive plate 122 is formed on interconnection structure 120. Interconnection structure 108 and a conductive plate 110 may be in contact with one of the source/drain regions and electrically coupled to an electrode of a capacitor formed in subsequent operations. Dielectric layer 144 is formed over interconnection structure 108 and interconnection structure 120. Then, via structure 124 is formed in dielectric layer 144 above interconnection structure 120.

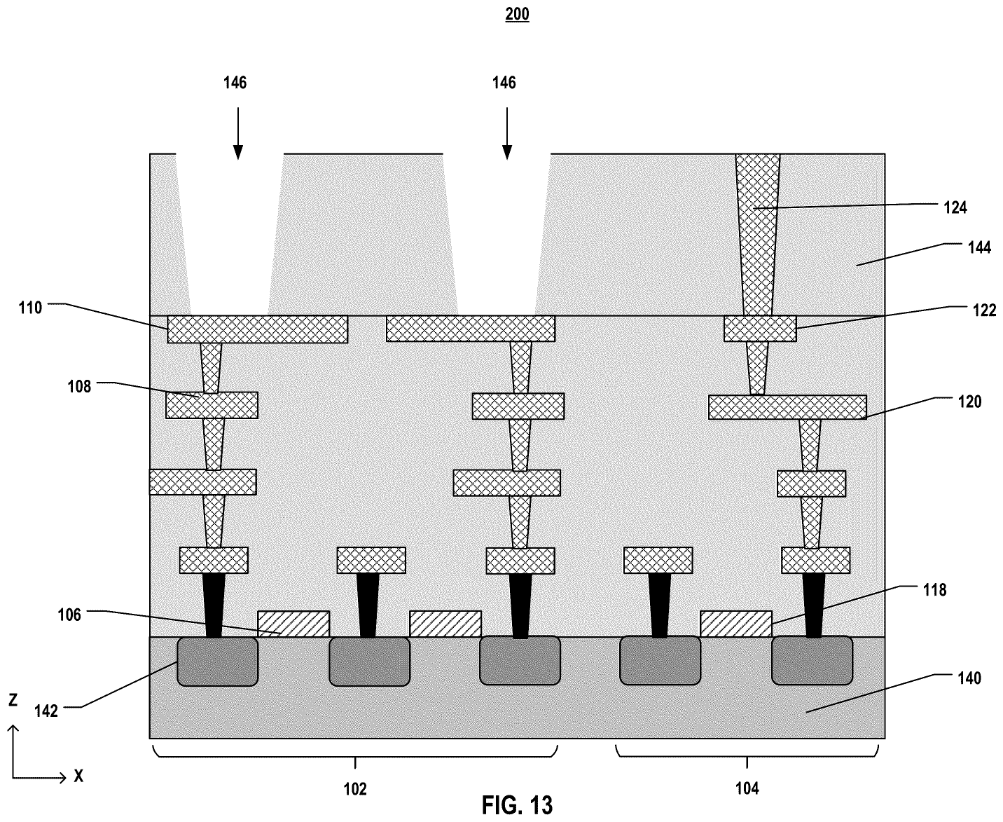

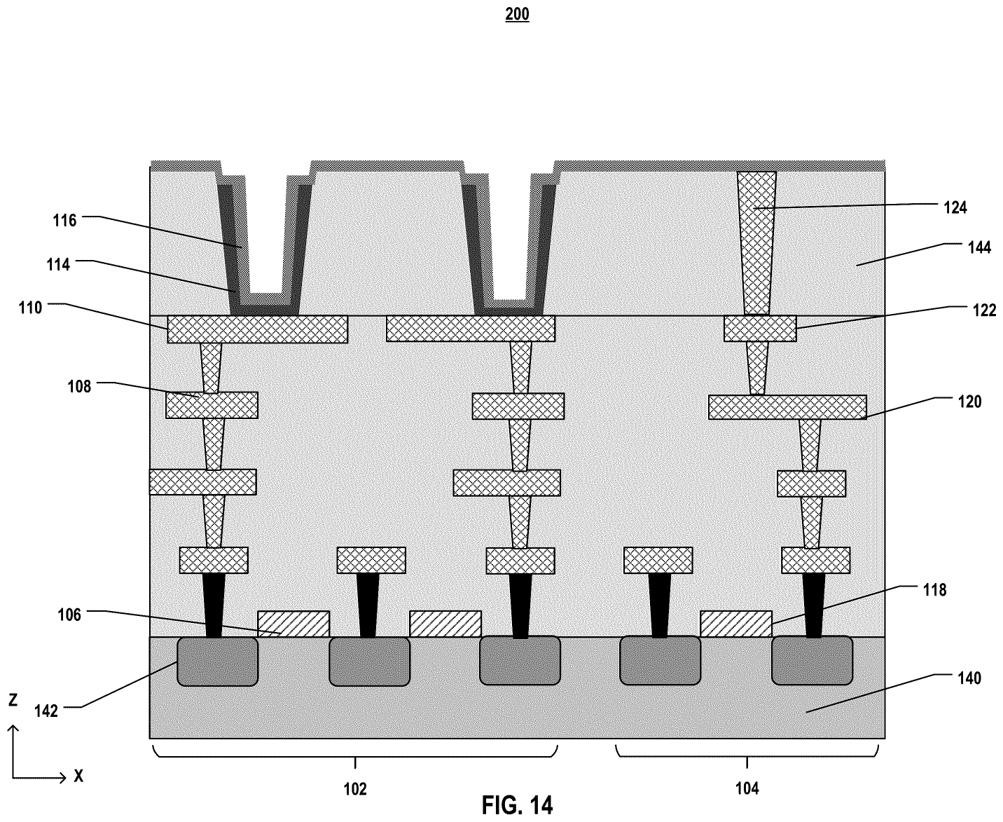

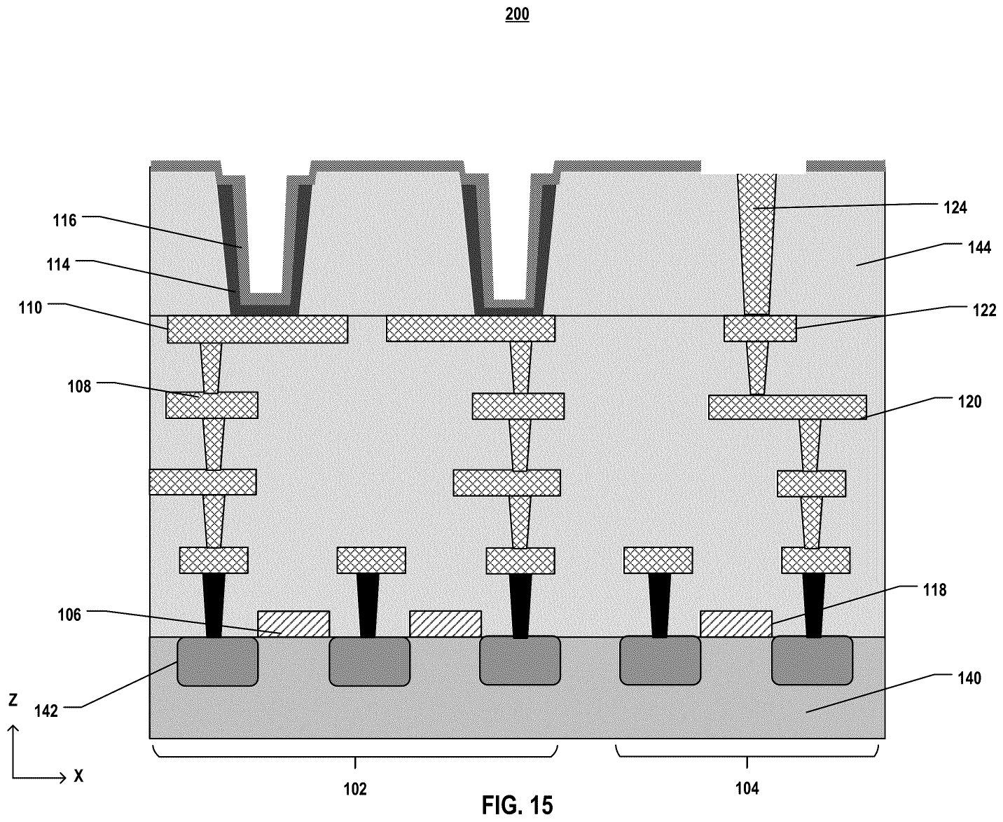

As shown in FIG. 13, openings 146 are formed in dielectric layer 144 to expose the top surface of conductive plates 110. Openings 146 may be formed by dry etch, wet etch, or other suitable processes. Then, as shown in FIG. 14, electrode 114 and ferroelectric layer 116 are sequentially and conformally formed in openings 146, and ferroelectric layer 116 further covers via structure 124 during the deposition process. Electrode 114 electrically contacts conductive plates 110. As shown in FIG. 15, an etch operation is performed to remove a portion of the ferroelectric layer 116 above via structure 124 to expose via structure 124. In some embodiments, ferroelectric layer 116 may include HfOx, ZrOx, or a combination of HfOx and ZrOx.

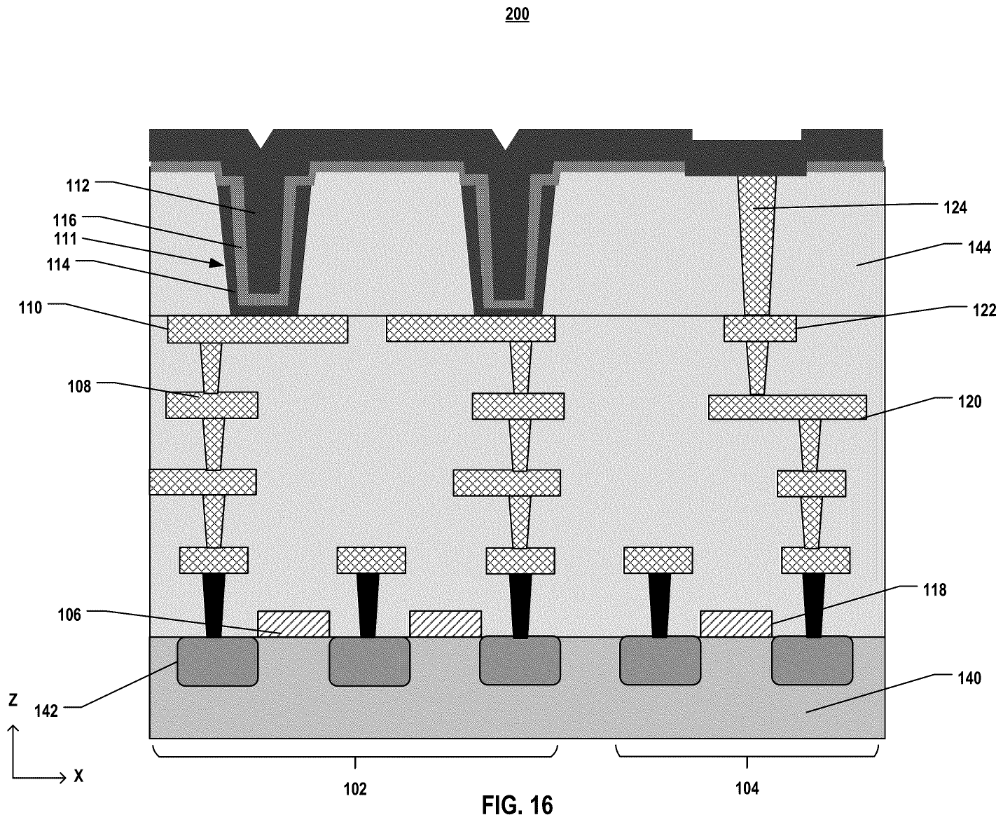

As shown in FIG. 16, electrode 112 is then conformally formed in openings 146 and over ferroelectric layer 116. Since ferroelectric layer 116 above via structure 124 is removed in the previous process, the conductive material forming electrode 112 may cover via structure 124 during the same process of forming electrode 112. In addition, the conductive material forming electrode 112 may be in direct contact with via structure 124.

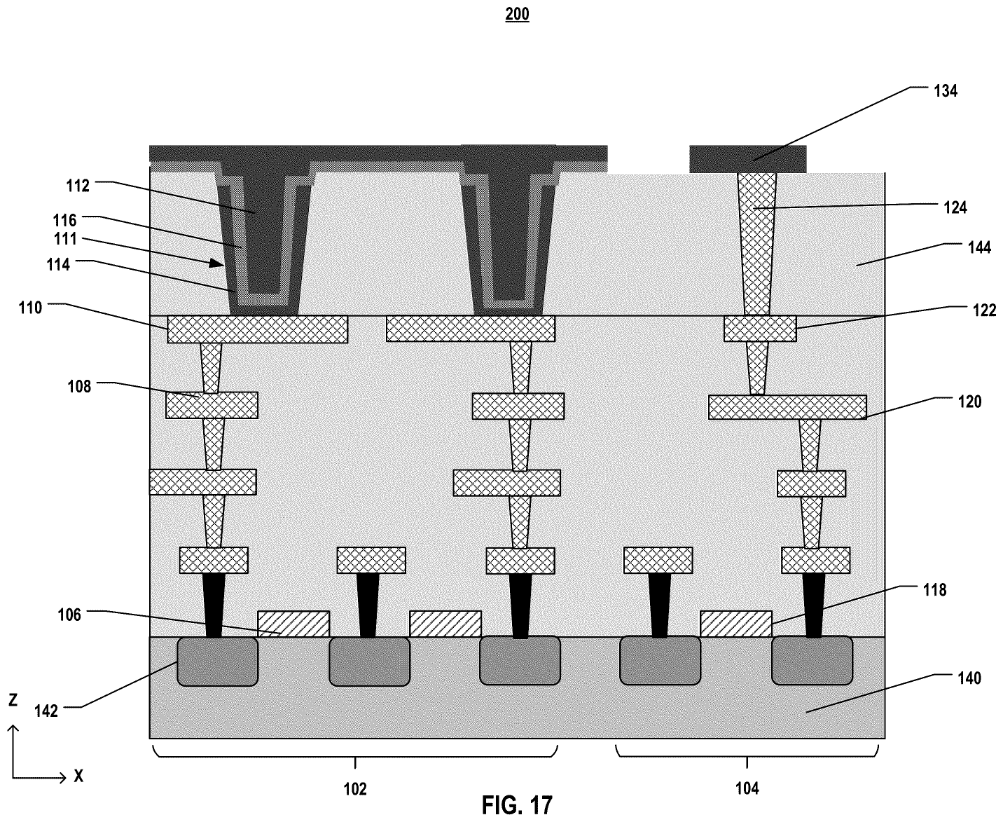

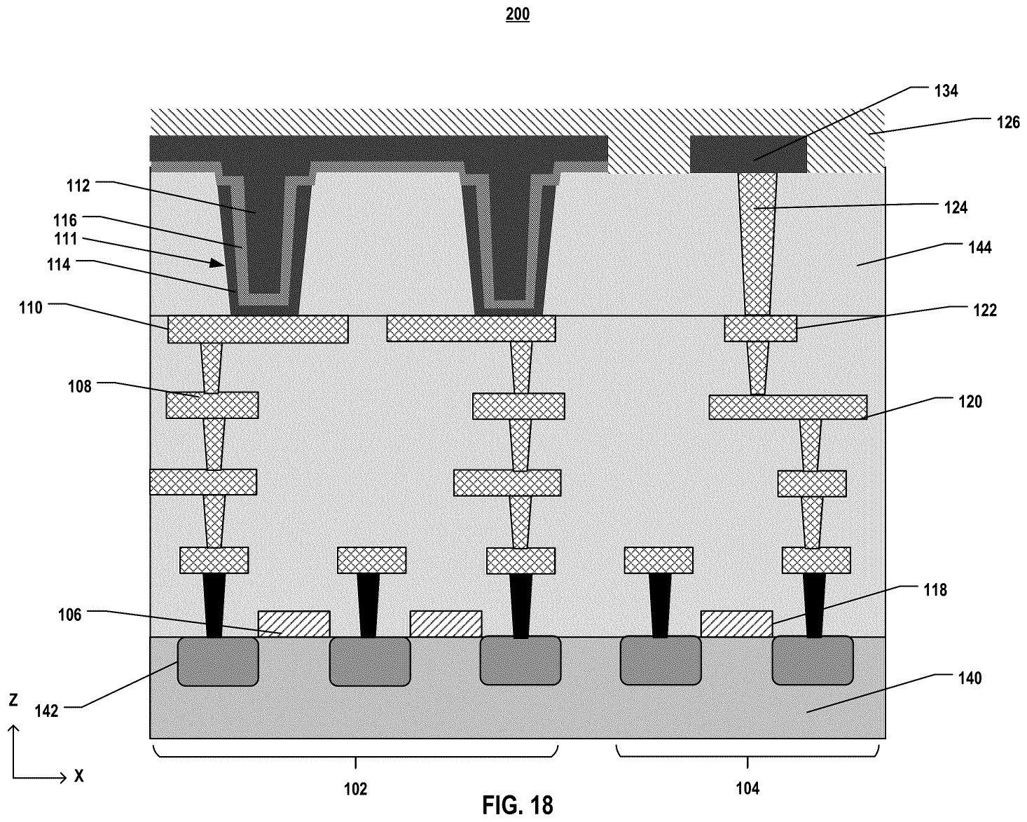

A planarization operation may be optionally performed to remove a top portion of electrode 112. Then, as shown in FIG. 17, an etch operation is performed to remove portions of electrode 112 and ferroelectric layer 116, and the conductive material above via structure 124 forms routing layer 134. Electrode 112 forms a portion of the routing layer above capacitor 111, and routing layer 134 and electrode 112 may include the same material. Then, as shown in FIG. 18, dielectric layer 126 is formed over routing layer 134, electrode 112, and dielectric layer 144.

In some embodiments, electrode 114, electrode 112, and routing layer 134 may include TiN, TiSiNₓ, TiAlNₓ, TiCNₓ, TaNₓ, TaSiNₓ, TaAlNₓ, WNₓ, WSiₓ, WCNₓ, Ru, RuOₓ, Ir, doped polysilicon, TCO, IrOₓ, or other suitable materials. In some embodiments, electrode 114, electrode 112, and routing layer 134 may include the same material(s). In some embodiments, electrode 114, electrode 112, and routing layer 134 may include different materials. Since the routing layer above capacitor 111 and the routing layer above periphery circuit in ferroelectric memory device 200 are formed in the same manufacturing process by the formation of electrode 112, the manufacturing process of ferroelectric memory device 200 may be further simplified ad the manufacturing cost may also be lowered.

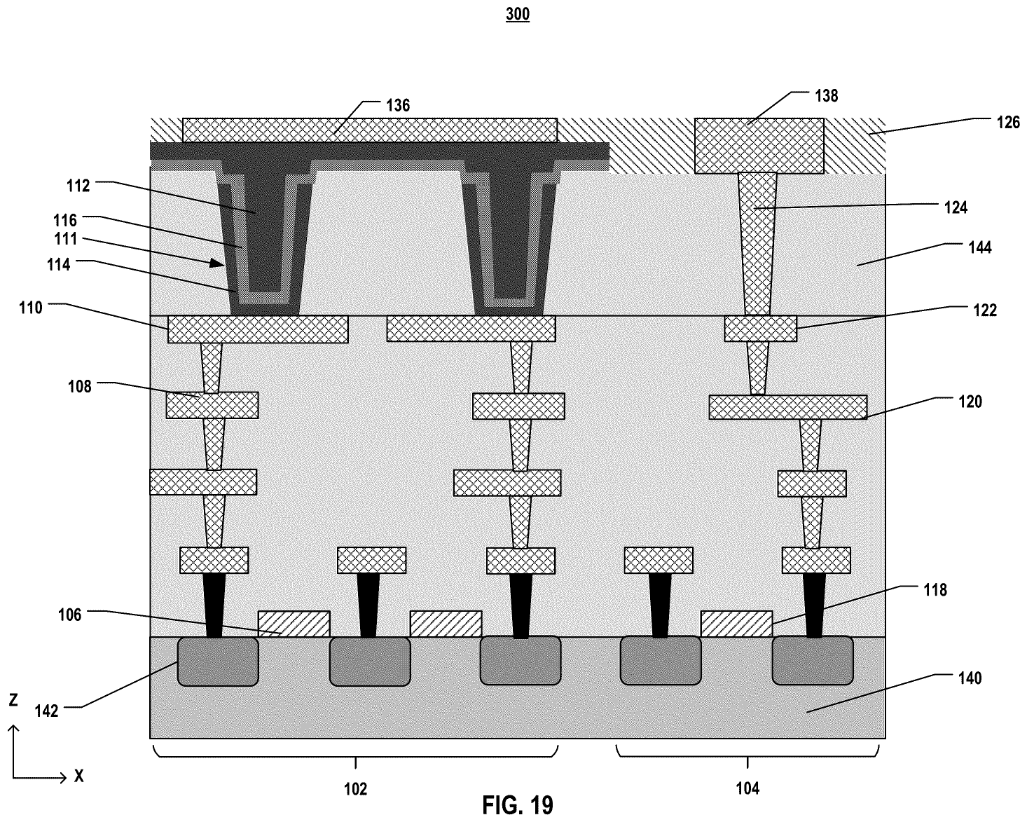

FIG. 19 illustrates a cross-section of ferroelectric memory device 300 at different stages of a manufacturing process, according to some aspects of the present disclosure. The structure of ferroelectric memory device 300 is similar to the structure of ferroelectric memory device 100, but routing layer 136 in ferroelectric memory device 300 is in direct contact with electrode 112. Different from ferroelectric memory device 100 that electrically connects routing layer 136 and electrode 112 through via structure 132, routing layer 136 in ferroelectric memory device 300 is in direct contact with electrode 112 without via structure 132.

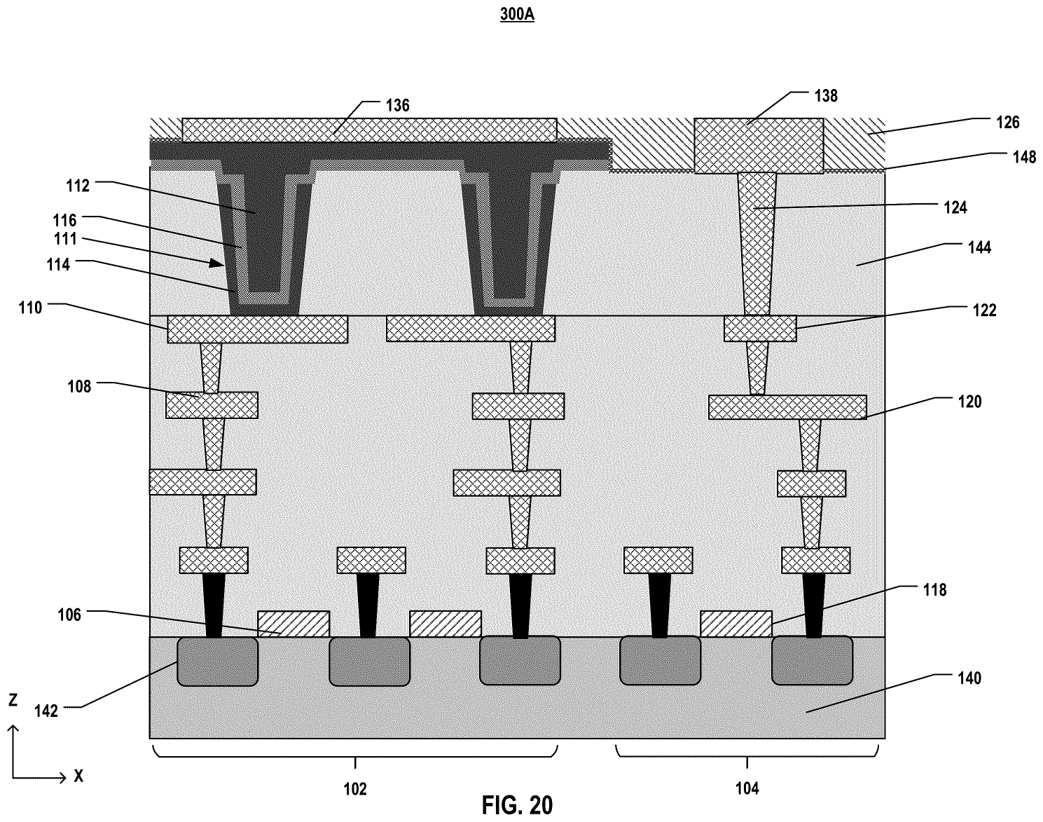

FIG. 20 illustrates a cross-section of a further exemplary ferroelectric memory device 300A at different stages of a manufacturing process, according to some aspects of the present disclosure. The structure of ferroelectric memory device 300A is similar to the structure of ferroelectric memory device 300, and protection layer 148 may be disposed over dielectric layer 144 and electrode 112. As shown in FIG. 20, before forming dielectric layer 126, protection layer 148 is deposited over dielectric layer 144 and electrode 112. In some embodiments, protection layer 148 may include AlOₓ. In some embodiments, protection layer 148 may include AlOₓ with SiN, SiON, or SiOC.

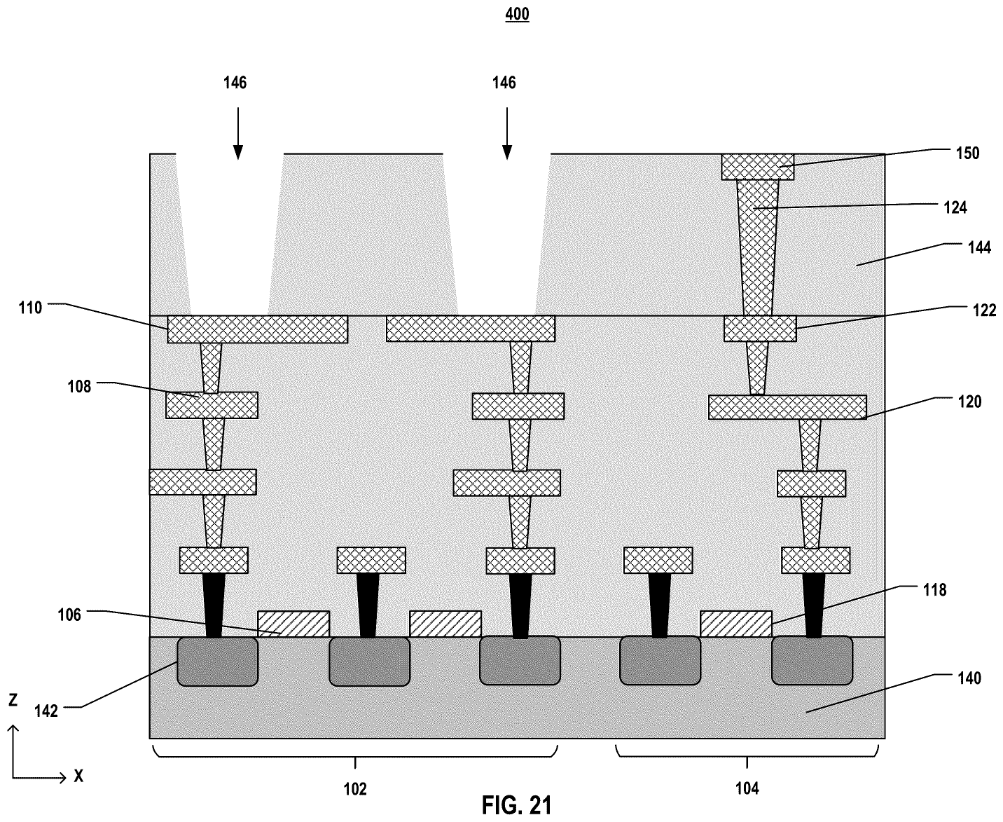

FIGS. 21-24 illustrate cross-sections of a further exemplary ferroelectric memory device 400 at different stages of a manufacturing process, according to some aspects of the present disclosure. As shown in FIG. 21, dielectric layer 144 is formed over interconnection structure 108 and interconnection structure 120, and via structure 124 is formed in dielectric layer 144 above interconnection structure 120. In addition, a conductive layer 150 is further formed in dielectric layer 144 above via structure 124. Openings 146 are formed in dielectric layer 144 to expose the top surface of conductive plates 110. Openings 146 may be formed by dry etch, wet etch, or other suitable processes.

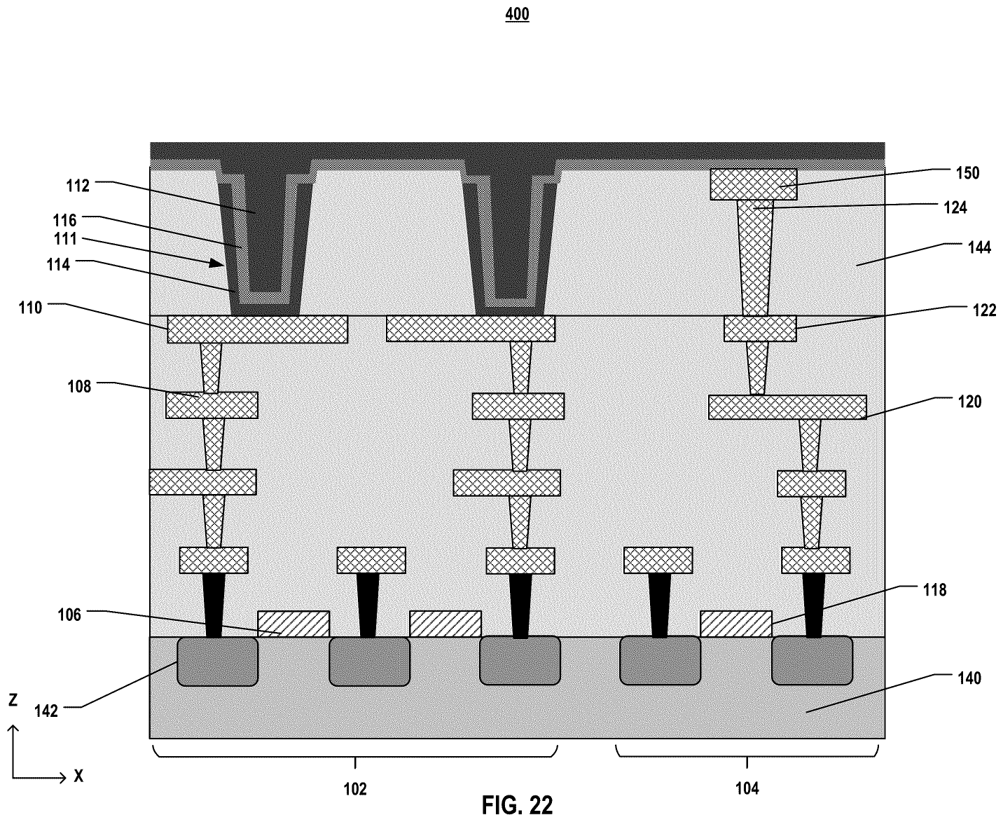

Then, as shown in FIG. 22, electrode 114, ferroelectric layer 116, and electrode 112 are sequentially and conformally formed in openings 146. A planarization operation may be optionally performed to remove a top portion of electrode 112. Ferroelectric layer 116 and electrode 112 may cover conductive layer 150. In some embodiments, ferroelectric layer 116 may include HfOx, ZrOx, or a combination of HfOx and ZrOx.

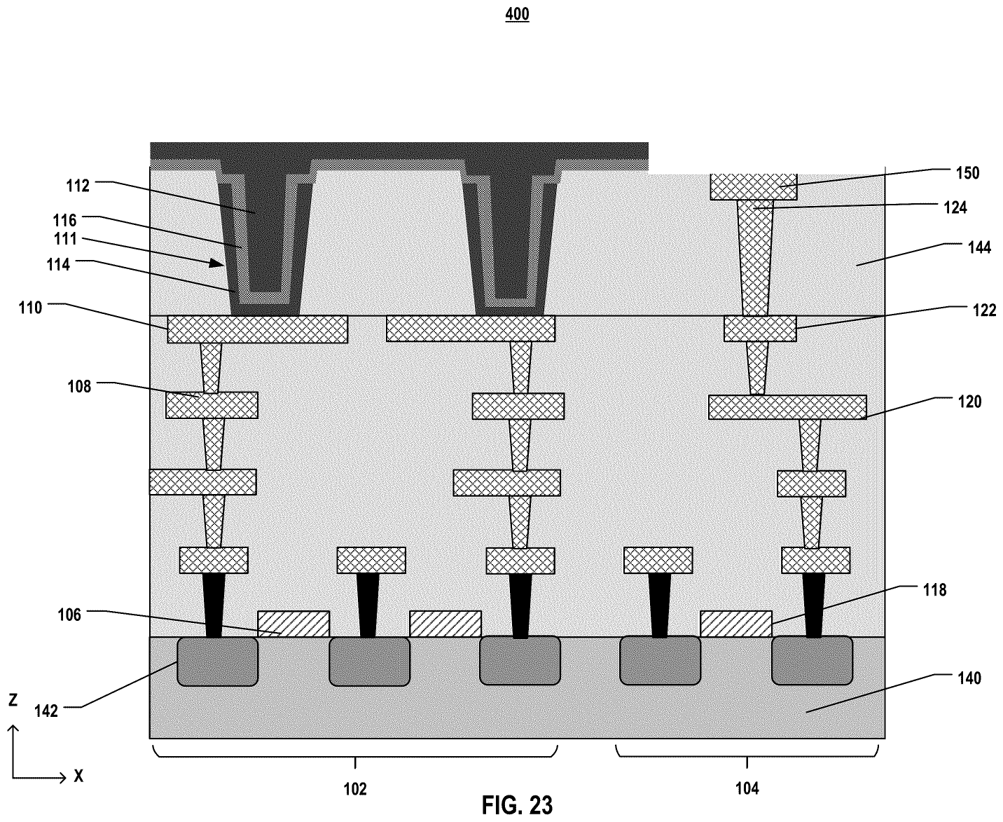

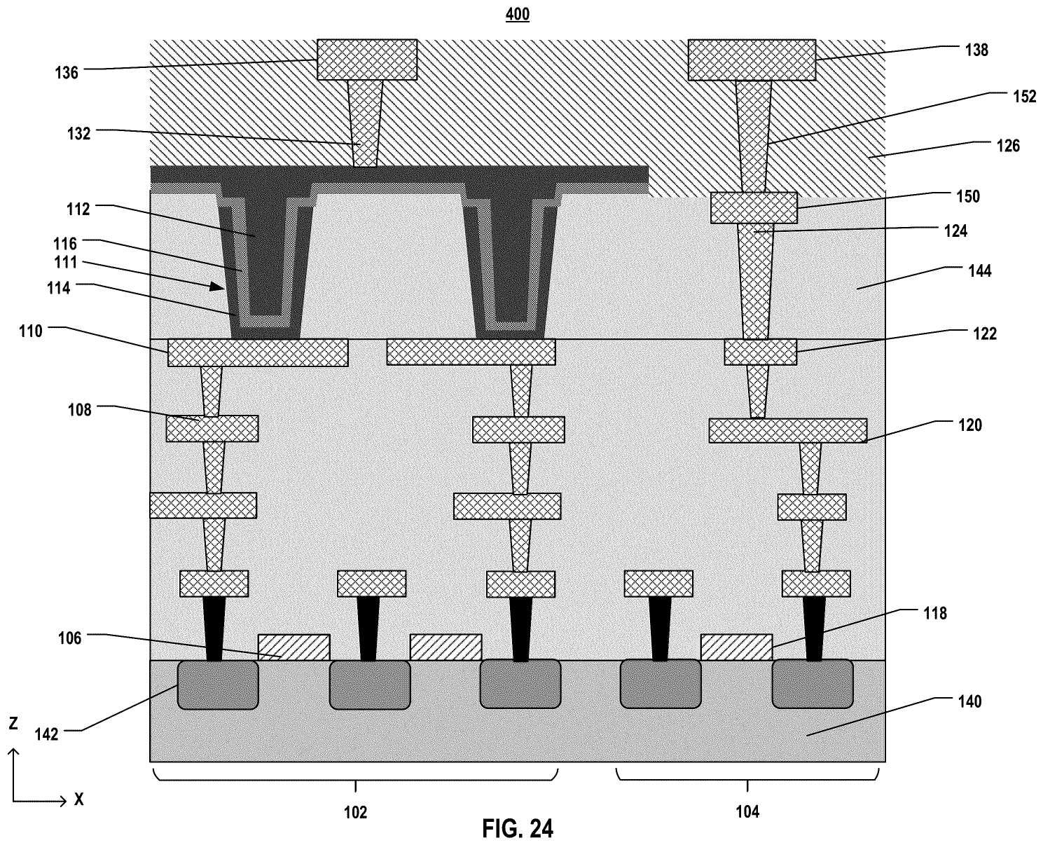

As shown in FIG. 23, portions of ferroelectric layer 116 and electrode 112 above periphery circuit 104 are removed to expose conductive layer 150. As shown in FIG. 24, dielectric layer 126 is formed over electrode 112 and the exposed conductive layer 150. Routing layer 136 is formed in dielectric layer 126 and is electrically connected to electrode 112 through via structure 132. Routing layer 138 is formed in dielectric layer 126 and is electrically connected to conductive layer 150 through a via structure 152.

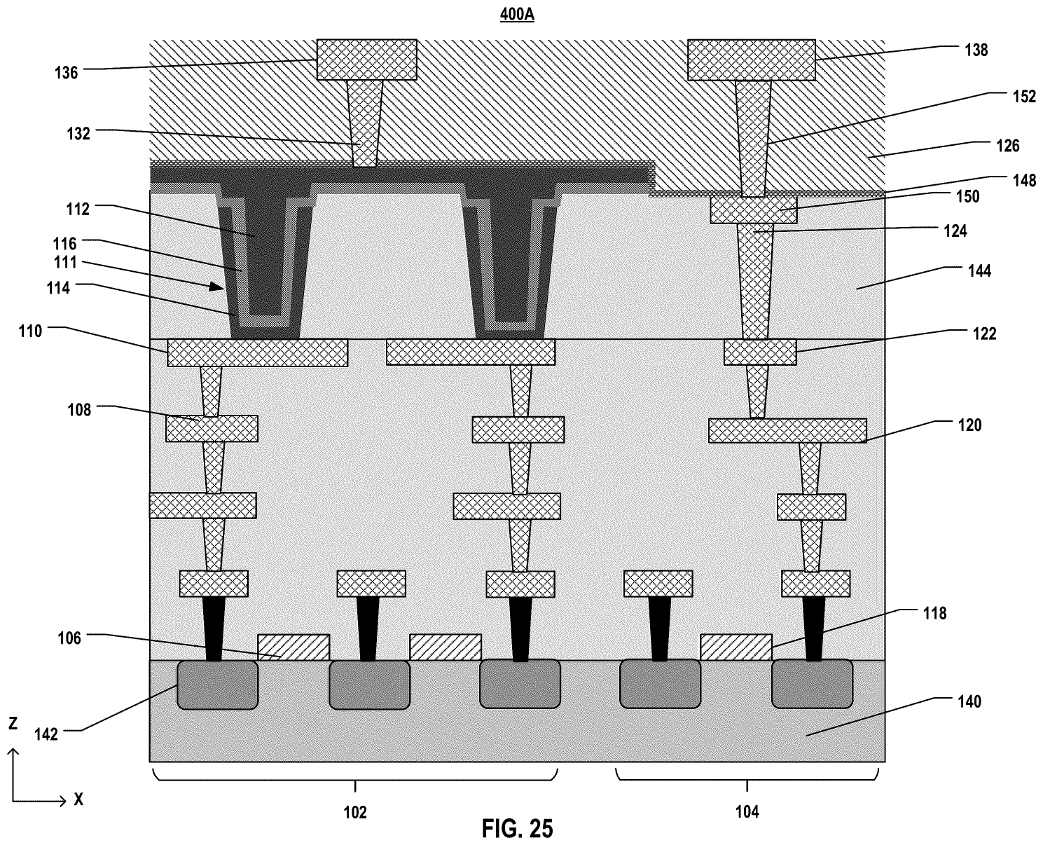

FIG. 25 illustrates a cross-section of a further exemplary ferroelectric memory device 400A at different stages of a manufacturing process, according to some aspects of the present disclosure. The structure of ferroelectric memory device 400A is similar to the structure of ferroelectric memory device 400, and protection layer 148 may be disposed over dielectric layer 144, electrode 112, and conductive layer 150. As shown in FIG. 25, before forming dielectric layer 126, protection layer 148 is deposited over dielectric layer 144, electrode 112, and conductive layer 150. In some embodiments, protection layer 148 may include AlOₓ. In some embodiments, protection layer 148 may include AlOₓ with SiN, SiON, or SiOC.

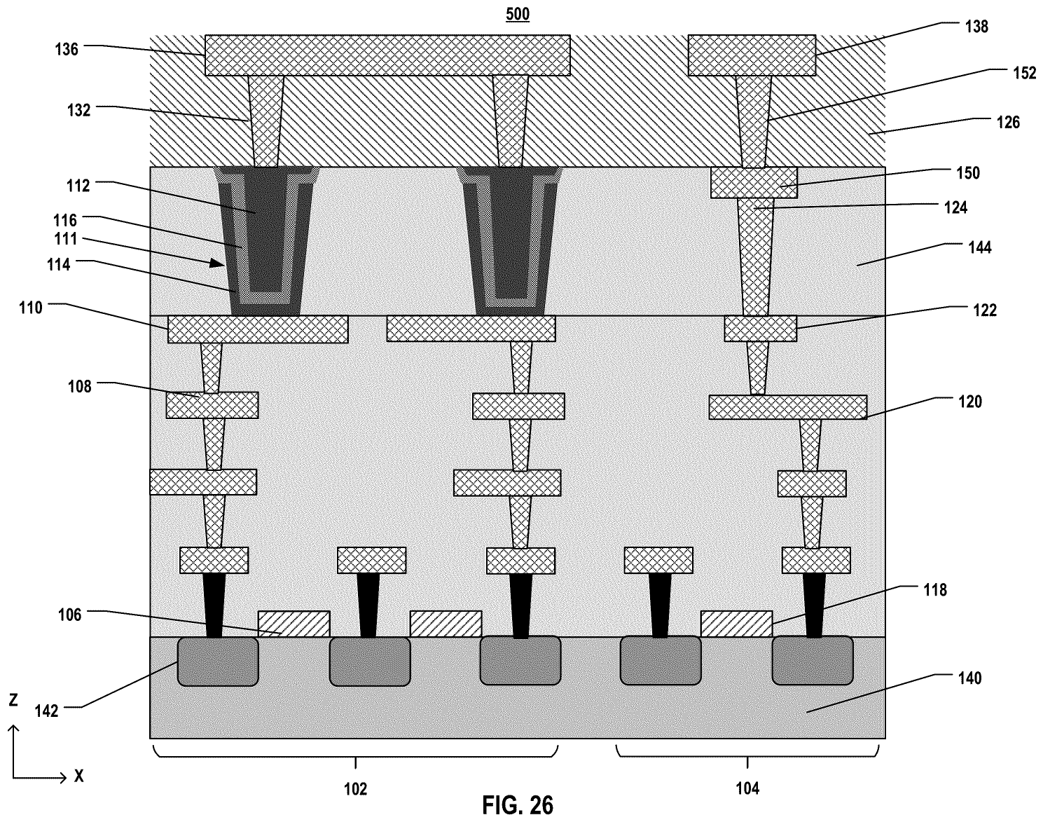

FIG. 26 illustrates a cross-section of a further exemplary ferroelectric memory device 500 at different stages of a manufacturing process, according to some aspects of the present disclosure. The structure of ferroelectric memory device 500 is similar to the structure of ferroelectric memory device 400, and a planarization operation is performed to remove a portion of capacitor 111 before forming dielectric layer 126.

As shown in FIG. 26, the planarization operation is performed to remove portions of electrode 112 and ferroelectric layer 116. After the planarization operation, the top surface of capacitor 111 is substantially coplanar with the top surface of conductive layer 150. In addition, more than one via structure 132 may be formed in dielectric layer 126 to electrically connect routing layer 136 and electrode 112.

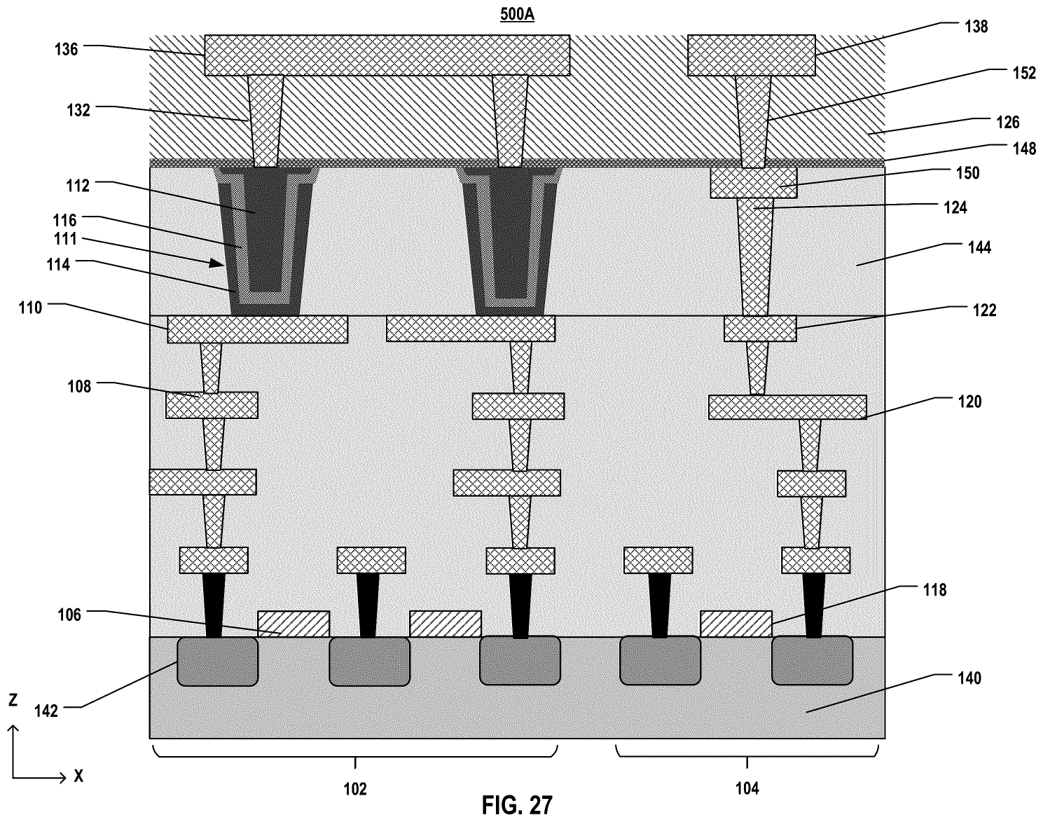

FIG. 27 illustrates a cross-section of a further exemplary ferroelectric memory device 500A at different stages of a manufacturing process, according to some aspects of the present disclosure. The structure of ferroelectric memory device 500A is similar to the structure of ferroelectric memory device 500, and protection layer 148 may be disposed over dielectric layer 144, electrode 112, and conductive layer 150. As shown in FIG. 27, before forming dielectric layer 126, protection layer 148 is deposited over dielectric layer 144, electrode 112, and conductive layer 150. In some embodiments, protection layer 148 may include AlOₓ. In some embodiments, protection layer 148 may include AlOₓ with SiN, SiON, or SiOC.

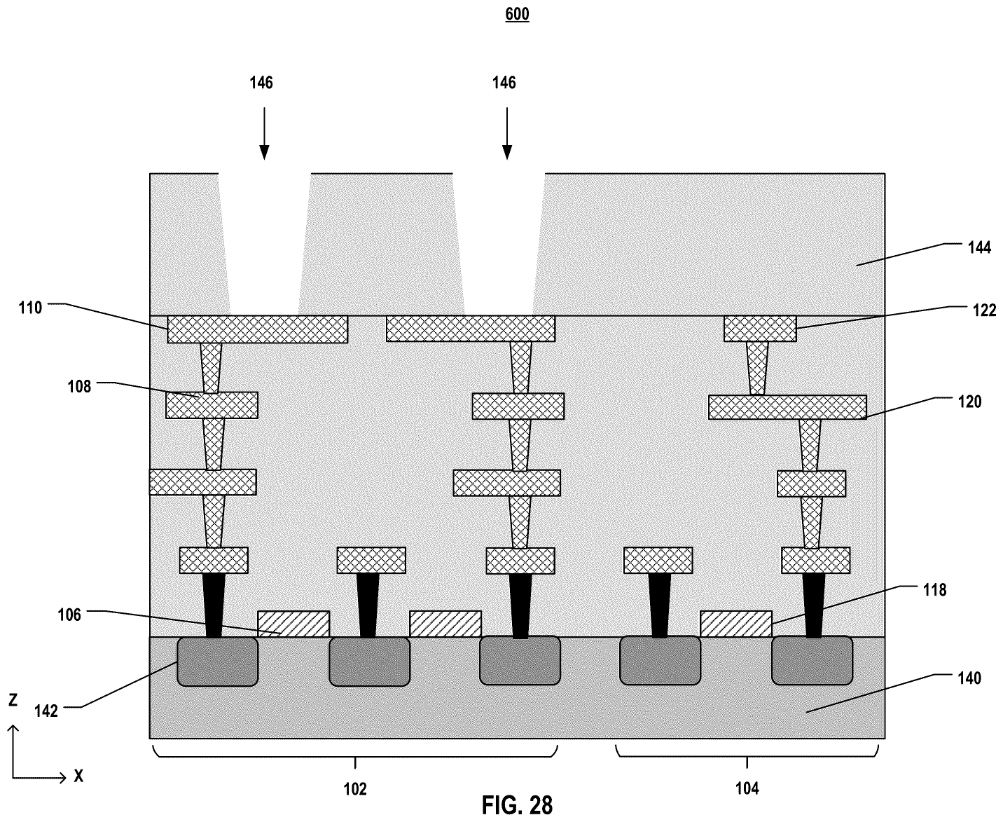

FIGS. 28-32 illustrate cross-sections of a further exemplary ferroelectric memory device 600 at different stages of a manufacturing process, according to some aspects of the present disclosure. As shown in FIG. 28, dielectric layer 144 is formed over interconnection structure 108 and interconnection structure 120. Openings 146 are formed in dielectric layer 144 to expose the top surface of conductive plates 110. Openings 146 may be formed by dry etch, wet etch, or other suitable processes.

It is understood that via structure 124 and routing 138 are not shown in ferroelectric memory device 600. FIGS. 28-32 is used for discussing the connection structure and manufacturing process between conductive plates 110 and capacitor 111. Varieties of structures and manufacturing processes of via structure 124 and routing 138 discussed above may also be applied to ferroelectric memory device 600.

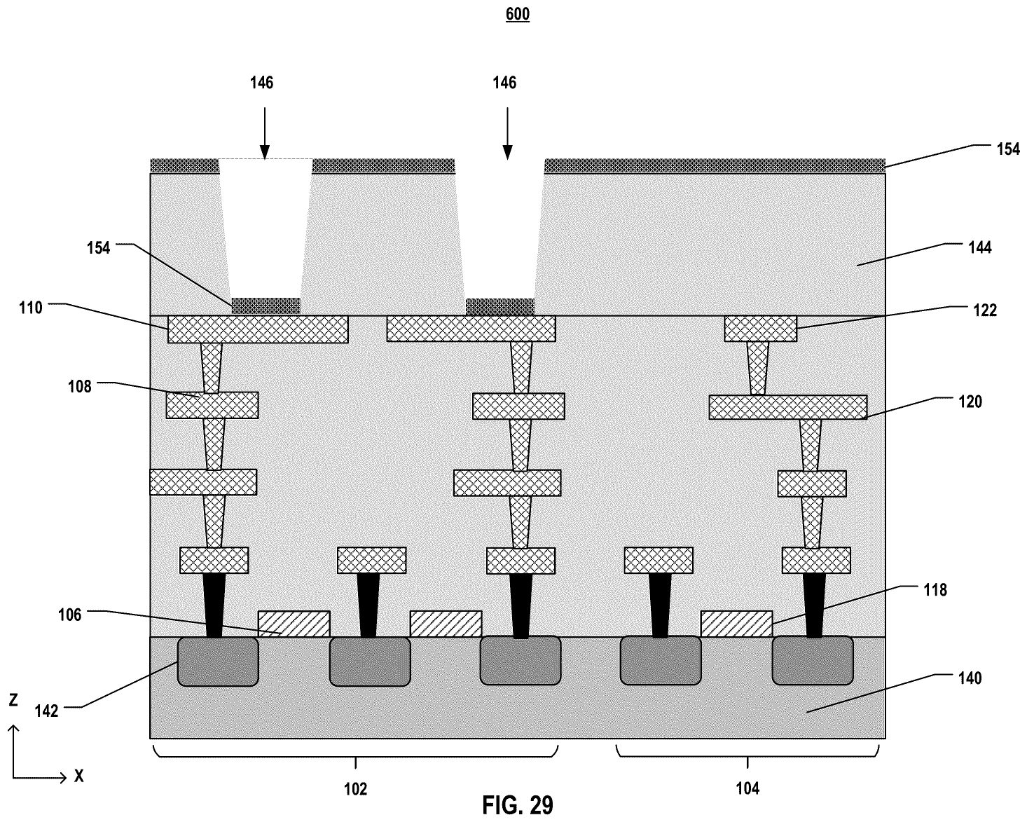

As shown in FIG. 29, a barrier layer 154 is formed on the top surface of dielectric layer 144 and on the bottom of openings 146. In some embodiments, barrier layer 154 may include TiN, TaN, Ta, or other suitable materials. In some embodiments, barrier layer 154 may be formed by CVD, PVD, a combination of CVD and PVD, or other suitable processes. In some embodiments, barrier layer 154 may prevent the diffusion between conductive plates 110, e.g., the cell landing island formed by Cu, and electrode 114.

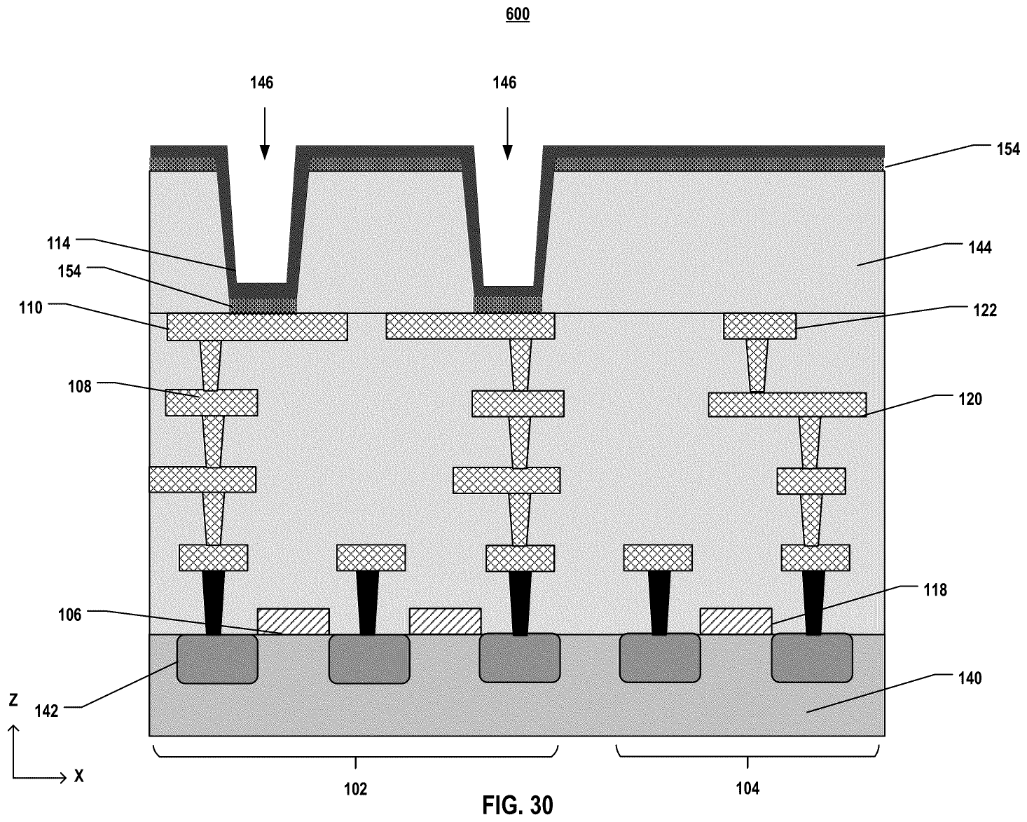

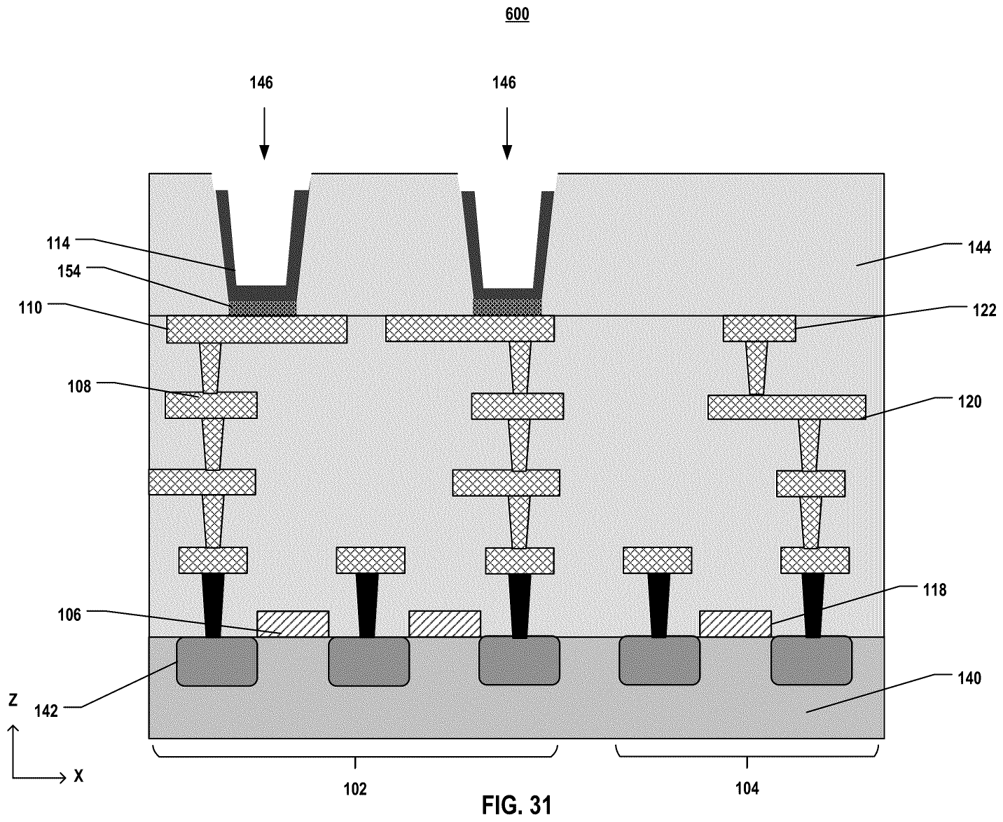

As shown in FIG. 30, electrode 114 is formed over barrier layer 154 and also covers the sidewalls of openings 146. As shown in FIG. 31, portions of barrier layer 154 and electrode 114 above dielectric layer 144 are removed. In some embodiments, portions of barrier layer 154 and electrode 114 above dielectric layer 144 may be removed by one or more planarization operations, e.g., chemical mechanical polishing (CMP). In some embodiments, portions of barrier layer 154 and electrode 114 above dielectric layer 144 may be removed by a blank etch operation, e.g., dry etch process. As shown in FIG. 31, in some embodiments, when etching the electrode 114, the top surface of the electrode 114 is lower than the top surface of dielectric layer 144, there is defined a step between the top surface of electrode 114 and the top surface of electric layer 144.

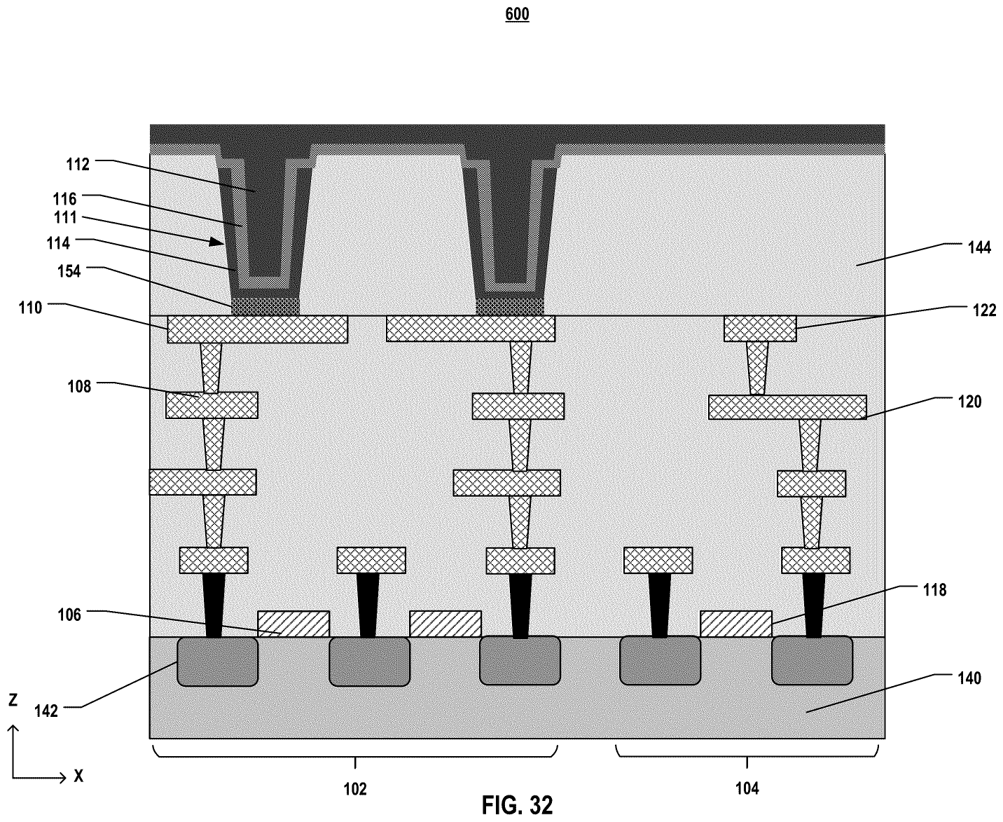

Then, as shown in FIG. 32, ferroelectric layer 116 and electrode 112 are sequentially and conformally formed in openings 146. Optionally, a further planarization operation may be performed to remove the top portion of electrode 112.

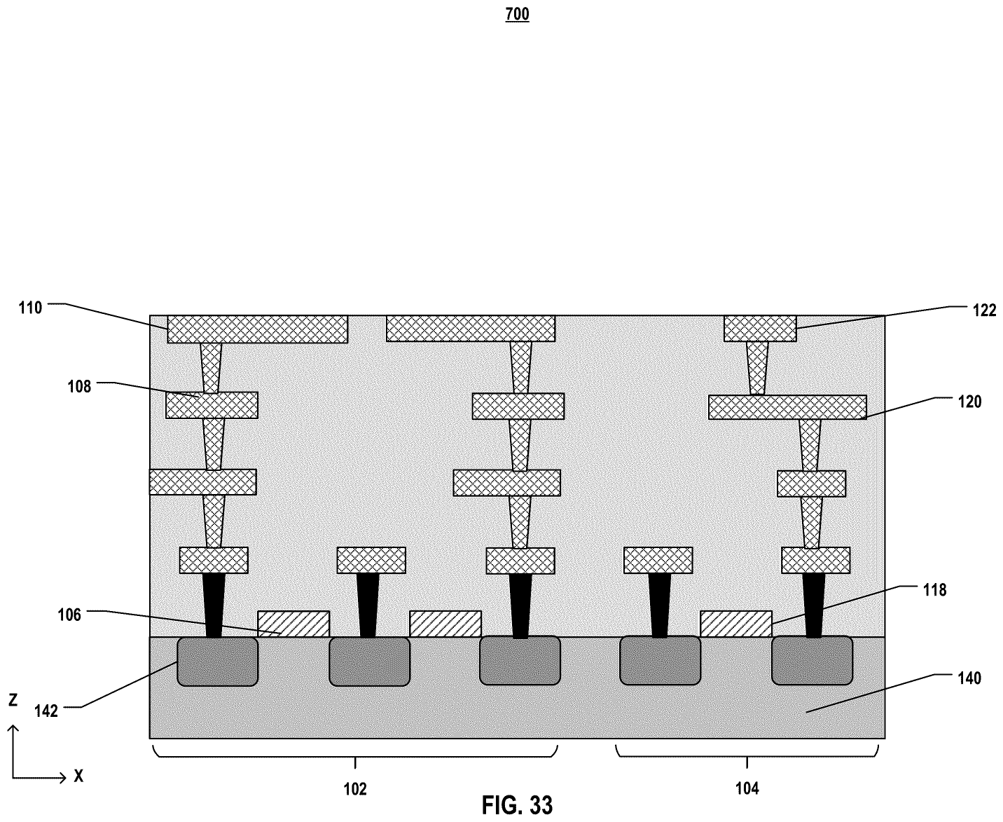

FIGS. 33-37 illustrate cross-sections of a further exemplary ferroelectric memory device 700 at different stages of a manufacturing process, according to some aspects of the present disclosure. As shown in FIG. 33, the semiconductor structure is formed over substrate 140. The semiconductor structure includes memory cell 102 (the cell region) and periphery circuit 104 (the periphery region). Interconnection structure 108 is formed over the cell region of the semiconductor structure, and interconnection structure 120 is formed over the periphery region of the semiconductor structure. Conductive plate 110 is formed on interconnection structure 108, and conductive plate 122 is formed on interconnection structure 120.

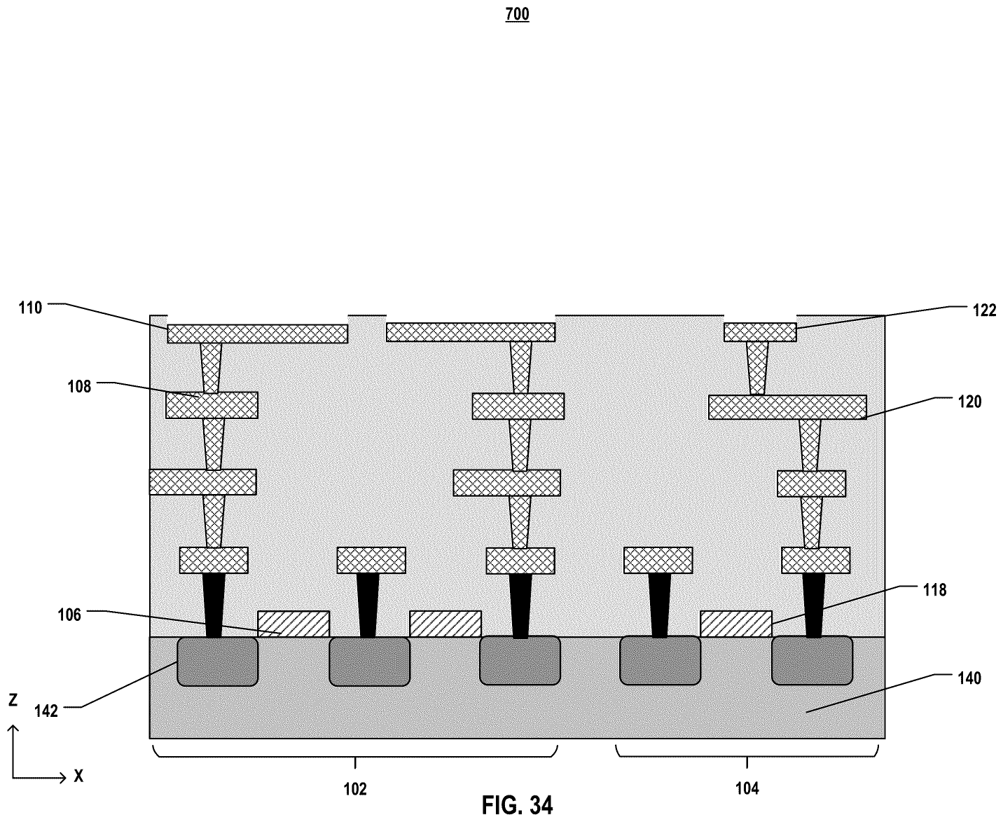

As shown in FIG. 34, an etch-back operation may be performed to remove a top portion of conductive plate 110 and a top portion of conductive plate 122. In some embodiments, the etch-back operation may include CMP. In some embodiments, when conductive plate 110 and conductive plate 122 are formed by low hardness metals, e.g., Cu, conductive plate 110 and conductive plate 122 may have a higher removal rate compared to the dielectric materials around conductive plate 110 and conductive plate 122 during the CMP operation. Hence, after the CMP operation, grooves may be formed on the top of conductive plate 110 and conductive plate 122, as shown in FIG. 34.

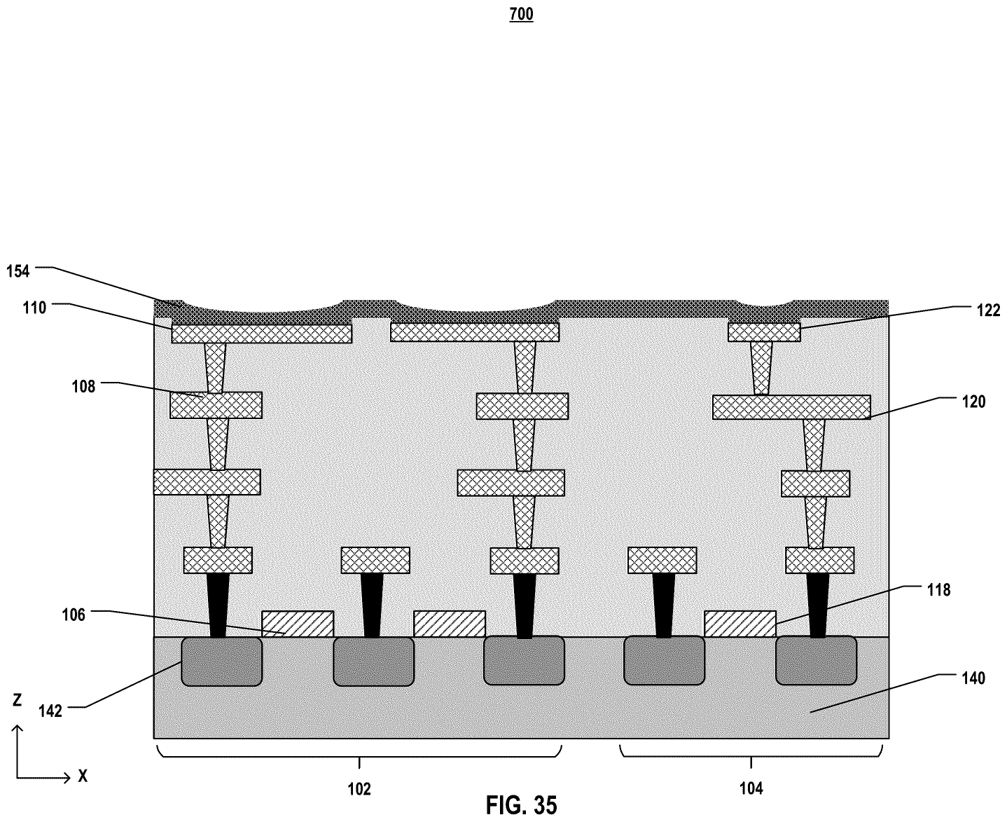

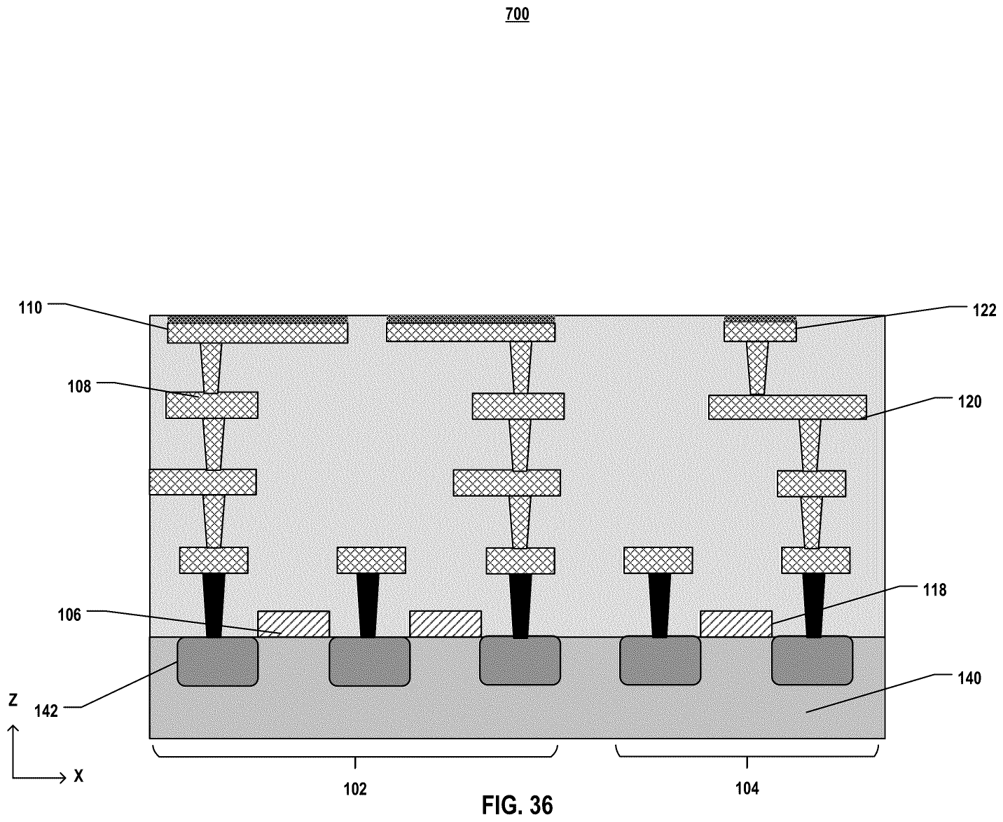

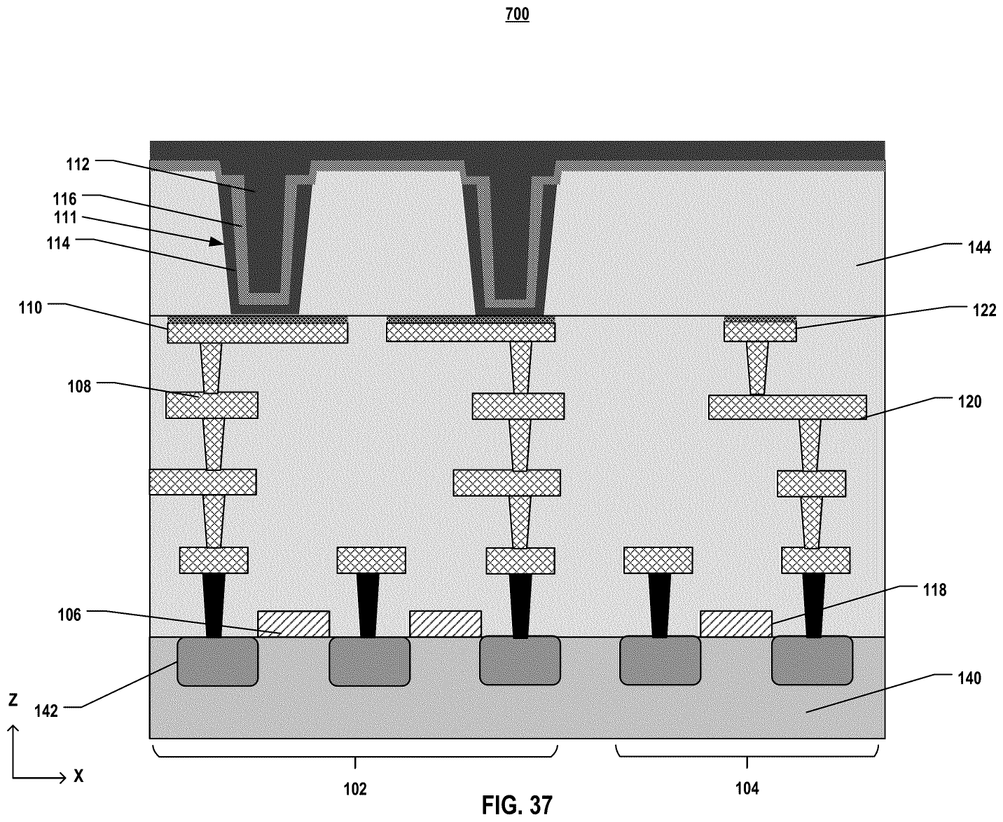

As shown in FIG. 35, barrier layer 154 is formed over conductive plate 110 and conductive plate 122 and fills in the grooves on conductive plate 110 and conductive plate 122. Then, a planarization operation, e.g., CMP, may be performed to remove a portion of barrier layer 154, and the CMP operation is stopped by the dielectric layer, e.g., silicon oxide, as shown in FIG. 36. After the formation of barrier layer 154 on conductive plate 110 and conductive plate 122, capacitor 111 may be formed in dielectric layer 144 on barrier layer 154, as shown in FIG. 37.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Embodiments of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all exemplary embodiments of the present disclosure as contemplated by the inventor(s), and thus, are not intended to limit the present disclosure and the appended claims in any way.

The breadth and scope of the present disclosure should not be limited by any of the above-described exemplary embodiments, but should be defined only in accordance with the following claims and their equivalents.

What is claimed is:

1. A memory device, comprising:
a plurality of memory cells, each memory cell comprising:
at least one first transistor;
at least one first interconnection layer formed over the at least one first transistor and in electrical contact with the at least one first transistor; and
at least one capacitor electrically coupled to the at least one first transistor through the at least one first interconnection layer, comprising:
a first electrode;
a second electrode surrounding at least a first portion of the first electrode, the second electrode electrically contacting the at least one first interconnection layer; and
a ferroelectric layer disposed between the first electrode and the second electrode;
a periphery circuit configured to control operations of the plurality of memory cells;
a routing structure disposed over the plurality of memory cells and the periphery circuit to electrically connect the plurality of memory cells and the periphery circuit; and
a second interconnection layer disposed over the routing structure,
wherein the at least one capacitor is disposed between the routing structure and a topmost conductive layer of the at least one first interconnection layer; and
wherein the second interconnection layer comprises no more than one conductive layer.

2. The memory device of claim 1, wherein the routing structure comprises a first routing layer in direct contact with the first electrode.

3. The memory device of claim 1, wherein the routing structure comprises a first routing layer in contact with the first electrode through a first via structure.

4. The memory device of claim 1, wherein the ferroelectric layer comprises HfOx, ZrOx, or a combination of HfOx and ZrOx.

5. The memory device of claim 1, wherein the periphery circuit further comprises:
at least one second transistor; and
a plurality of third interconnection layers electrically coupled to the at least one second transistor,
wherein the plurality of third interconnection layers are in contact with the routing structure through at least one second via structure.

6. The memory device of claim 1, wherein the routing structure further comprises a second routing layer coplanar to the first routing layer in contact with the plurality of second interconnection layers through the at least one second via structure.

7. A memory device, comprising:
a plurality of memory cells, each memory cell comprising:
at least one first transistor;
at least one first interconnection layer formed over the at least one first transistor and in electrical contact with the at least one first transistor;
a first conductive layer formed over the at least one first interconnection layer, the first conductive layer electrically coupled to the at least one first transistor through the at least one first interconnection layer; and
at least one capacitor formed on the first conductive layer, comprising:
a first electrode;
a second electrode surrounding at least a first portion of the first electrode, the second electrode electrically contacting the first conductive layer; and
a ferroelectric layer disposed between the first electrode and the second electrode; and
a periphery circuit configured to control operations of the plurality of memory cells,
wherein the first electrode of the plurality of memory cells functions as a routing structure between the plurality of memory cells.

8. The memory device of claim 7, further comprising:
a barrier layer disposed between the first conductive layer and the second electrode.

9. The memory device of claim 8, wherein the barrier layer comprises tantalum or tantalum nitride.

10. The memory device of claim 8, wherein a width of the barrier layer is equal to or larger than a width of the second electrode.

11. The memory device of claim 7, wherein the first electrode of one memory cell is in electric contact with the first electrode of another memory cell.

12. The memory device of claim 7, wherein the periphery circuit further comprises:
at least one second transistor; and
a plurality of second interconnection layers electrically coupled to the at least one second transistor,
wherein the plurality of second interconnection layers are in contact with the routing structure through at least one via structure.

13. The memory device of claim 12, wherein a first height of the at least one capacitor is equal to or less than a second height of the at least one via structure.

14. A method for forming a ferroelectric memory, comprising:
forming a semiconductor structure over a substrate, the semiconductor structure comprising a cell region and a periphery region;
forming a first interconnection structure over the cell region of the semiconductor structure and a second interconnection structure over the periphery region of the semiconductor structure;
forming a dielectric layer over the first interconnection structure and the second interconnection structure;
forming a capacitor in the dielectric layer above the first interconnection structure and a via structure in the dielectric layer above the second interconnection structure; and
forming a routing structure over the capacitor and the via structure.

15. The method of claim 14, wherein forming the capacitor in the dielectric layer above the first interconnection structure and the via structure in the dielectric layer above the second interconnection structure, further comprises:
forming a first opening in the dielectric layer above the first interconnection structure;
forming the capacitor in the first opening, the ferroelectric memory comprising a first electrode, a second electrode surrounding at least a first portion of the first electrode, and a ferroelectric layer disposed between the first electrode and the second electrode;
forming a second opening in the dielectric layer above the second interconnection structure; and
forming the via structure in the second opening.

16. The method of claim 15, further comprising:
forming a linear layer over the capacitor and the via structure.

17. The method of claim 15, wherein forming the routing structure over the capacitor and the via structure, further comprises:
forming a first routing layer in contact with the via structure; and
utilizing a portion of the first electrode as a second routing layer.

18. The method of claim 14, wherein forming the routing structure over the capacitor and the via structure, further comprises:
forming a first routing layer in contact with the via structure; and
forming a second routing layer in direct contact with the first electrode.

19. The method of claim 14, further comprising:
forming a barrier layer between the first interconnection structure and the capacitor.

20. The method of claim 19, wherein the barrier layer comprises tantalum or tantalum nitride.
